(19) United States
(12) Patent Application Publication
(10) Pub. No.: US 2026/0326146 A1
(43) Pub. Date: Oct. 22, 2026

(54) GUIDED AD INFINITUM ASSEMBLY OF MIXED-METAL OXIDE ARRAYS FROM A LIQUID METAL

(71) Applicant: North Carolina State University, Raleigh, NC (US)

(72) Inventors: Martin Thuo, Apex, NC (US); Julia Chang, Raleigh, NC (US)

(21) Appl. No.: 19/647,017

(22) Filed: Apr. 14, 2026

Related U.S. Application Data
(60) Provisional application No. 63/790,295, filed on Apr. 17, 2025.

(51) Int. Cl. B05D 5/00; B05D 3/02; B05D 3/14; B05D 7/24; H10K 10/46

(52) U.S. Cl. CPC B05D 5/00; B05D 3/0254; B05D 3/145; B05D 7/24; H10K 10/466

(57) ABSTRACT

A method for forming an array comprising at least one layer of organometallic deposits is disclosed. Each of the organometallic deposits is a wire, a shape, and/or a functional unit and has a micro and/or a nano dimension. The organometallic deposits are formed by i) providing a solution to openings of channels, ii) forming and pinning down organometallic adducts as the solution penetrates the channels; and iii) evaporating at least a portion of the solution to form the organometallic deposits. The solution comprises synthon metal ions, an acid, and a solvent.

### CROSS-REFERENCE

This application claims the benefit of United States Provisional Patent Application Ser. No. 63/790,295 filed on Apr. 17, 2025, which is incorporated herein by reference in its entirety.

### STATEMENT OF GOVERNMENT INTEREST

This invention was made with government support under 2243104 awarded by the National Science Foundation. The government has certain rights in the invention.

### TECHNICAL FIELD

One or more aspects of the present invention relate to methods of manufacturing nano-to micro-arrays useful in modern electronics and optics. Specifically, one or more aspects of the invention relate to a facile mixed-metal array fabrication method based on guided self-assembly of polymerizing organometallic adducts derived from the passivating oxides of a ternary liquid metal to create mixed metal wires.

### BACKGROUND

The need for device fabrication efficiency has been exacerbated by global demand for electronics. Low energy consumption, efficient fabrication, and lower cost always conflict with the pursuit of enhanced device performance. Arrays, the periodic arrangement of building blocks, serve as the basis of many functional devices (e.g., optical metamaterials or integrated circuits). Fabrication of nanoarrays relies on efficient organization methods with traditional approaches falling into two main subcategories, viz; bottom-up and top-down methods. Bottom-up methods assemble as-synthesized building blocks into arrays based on interactions (covalent bonds, hydrogen bonds, and electrostatic interactions, among others). Top-down methods construct arrays from bulk material generally via selective abstraction (e.g., e-beam lithography, laser writing, and 3D printing). These strategies, however, often fail to reconcile the contradiction between precision across length scales and fabrication efficiency. Template-assisted fabrication techniques produce multi-scale arrays in high yields without compromising quality. Serving as masks, stamps, or maps, templates are applied in lithographic (phase-shifting or edge lithography), imprinting/embossing, or self-assembly processes to produce large-area arrays. Despite enhanced efficiency realized by adopting templates, multiple post-processing steps are often necessary to endow functionality to the as-obtained patterns, which can introduce defects as well as increase fabrication cost. New fabrication techniques are therefore needed to continue producing high-precision, functional devices at manageable costs.

### SUMMARY

In some aspects, the techniques described herein relate to a method for forming an array, the method including: (a) forming a layerₓ on a substrate, wherein x=1, the layerₓ is a layer₁, and the layer₁ is attached to the substrate. The forming of the layerₓ includes forming organometallic deposits. The forming of the organometallic deposits includes: (i) providing a solution to openings of channels; (ii) forming and pinning down organometallic adducts as the solution penetrates the channels; and (iii) evaporating at least a portion of the solution to form the organometallic deposits. The solution includes synthon metal ions, an acid, and a solvent. The solution is formed by etching metal particles with the acid and the solvent proximate the openings or feeding the solution through the openings. Each of the organometallic deposits includes a wire, a shape, and/or a functional unit, and each of the organometallic deposits has a micro and/or a nano dimension.

In some aspects, the techniques described herein relate to a method for forming an array, the method including: (a) forming a layerₓ, (b) forming a layer₍ₓ₊₁₎ adjacent to the layerₓ along an axis of interest; and (c) incrementing x by 1 and repeating step b) until a set number of layers is reached. When x=1, the layerₓ is layer₁, and layer₁ is attached to a substrate. The forming of the layerₓ and of the layer₍ₓ₊₁₎ includes forming organometallic deposits. The axis of interest of the layer₍ₓ₊₁₎ and the axis of interest of the layerₓ are different. The forming of the organometallic deposits includes: (i) providing a solution to openings of channels; (ii) forming and pinning down organometallic adducts as the solution penetrates the channels; and (iii) evaporating at least a portion of the solution to form the organometallic deposits. The solution includes synthon metal ions, an acid, and a solvent. The solution is formed by etching metal particles with the acid and the solvent proximate the openings or feeding the solution through the openings. Each of the organometallic deposits includes a wire, a shape, and/or a functional unit, and each of the organometallic deposits has a micro and/or a nano dimension.

In some aspects, the techniques described herein relate to an array including at least one layer, wherein the at least one layer includes organometallic deposits. The organometallic deposits have a micro and/or a nano dimension, and the organometallic deposits include a wire, a shape, and/or a functional unit.

### BRIEF DESCRIPTION OF THE DRAWINGS

The present disclosure is illustrated and described herein with reference to the various drawings, in which like reference numbers are used to denote like system components/method steps, as appropriate, and in which:

FIG. 1 is a schematic of an organometallic adduct showing metal ions, Mₐ, M_{b}, and M_{c}.

FIG. 2A is a perspective view of a schematic of the open channel process for making organometallic deposits (i.e., D-Met process), and FIG. 2B is a micrograph of the wires (i.e., organometallic deposits) obtained in Ex. 2.

FIG. 3A is a perspective view of a schematic of the closed channel process for making organometallic deposits, and FIG. 3B is a micrograph of the wires (i.e., organometallic deposits) obtained in Ex. 3.

FIG. 3C is a schematic showing an alternative embodiment for the process of forming organometallic deposits.

FIG. 4A is a graph summarizing the corresponding penetrativity and vapor pressure (Pvap) for the acid/solvent mixtures used in Ex. 4, and FIG. 4B contains three micrographs of the wires made using each of the three different acid/solvent mixtures in Ex. 4.

FIG. 5A is a micrograph of the dissolving zone, FIG. 5B is a micrograph of the growth zone, and FIG. 5C is a micrograph of the collection zone, and FIG. 5D is Energy Dispersive X-ray Spectroscopy (EDS) elemental mapping of the array made in Ex. 5.

FIG. 5E is a set of micrographs of wires with different widths made in Ex. 5.

FIG. 6A is a micrograph of organometallic deposits with a complex pattern, FIG. 6B is a micrograph of an array of organometallic deposits in the form of a pattern with right-angle corners and curvatures, and FIG. 6C is a micrograph of an array comprising a pattern of micro-rotor mimicking designs.

FIGS. 6D, 6E, and 6F are top view, front view, and side view schematics, respectively, of a section of the complex pattern shown in FIG. 6C.

FIG. 7A is a micrograph of the array obtained in Ex. 7 at a magnification of 2 μm, and FIG. 7B is a micrograph of the same array at a magnification of 500 nm.

FIG. 8A is a schematic of the fabrication of a 2-layer array, FIG. 8B shows a micrograph of the 2-layer array obtained in Ex. 8, FIG. 8C is an elemental mapping of the same 2-layer array showing homogeneous composition, and FIG. 8D is a micrograph of a second 2-layer array with narrower wires than the 2-layer array shown in FIG. 8B.

FIG. 9A is a set of Scanning Electron Microscope (SEM) images of pristine and ambient calcined nanowire arrays, FIG. 9B contains atomic force microscope (AFM) mapping, cross-section analysis before and after calcination, along with summaries of wire height and width change for FM microwire arrays, FIG. 9C contains atomic force microscope (AFM) mapping, cross-section analysis before and after calcination, along with summaries of wire height and width change for FM nanowire arrays, FIG. 9D is a graph showing the metal elemental contents summary of Field's metal particle, pristine and calcined Field's metal microwire array as well as calcined Field's metal nanowire array, and FIG. 9E is an X-ray Photoelectronic Spectroscopy (XPS) graph for the pristine and calcined FM microarrays.

FIG. 10A contains two micrographs of the arrays made with microwire-sized wires and with nanowire-sized wires, FIG. 10B is an EDS mapping of microwire arrays made from eutectic Indium Tin (IT) particles, and FIG. 10C shows comparative analysis between the microwire arrays and the nanowire arrays before and after they were calcined.

FIG. 11A is a current-voltage plot of pristine and calcined FM microwires, FIG. 11B is a current-voltage plot for pristine and calcined IT microwires, FIG. 11C is a schematic of the FET conductivity testing set-up, FIG. 11D is a current-voltage graph of the FM microwire array, and FIG. 11E is a current-voltage graph of the IT microwire array.

FIG. 12A is an SEM image of 2-layer array cross-sections highlighting conformal contact points between the 1st and 2nd layers in nanowire arrays, and FIG. 12B shows an SEM image of an isolated free-standing unit structurally analogous to some FinFet morphologies.

FIG. 13A is a schematic of an optical filter, FIG. 13B is a transmission spectrum under transverse magnetic polarized light and the corresponding simulation result, and FIG. 13C is a transmission spectrum under transverse electric polarized light and the corresponding simulation result.

FIG. 14 contains SEM and EDS images of the In—C junction on the left/top and the In—Bi junction on the right/bottom.

FIG. 15 contains SEM and EDS spectrographs corresponding to the arrays made using single-component particles in Ex. 15.

FIG. 16A is a top view schematic of the array made with a curved substrate, FIG. 16B is a front view schematic of the array made with the curved substrate used in Ex. 16 and FIG. 16C is a side view schematic of the array made with the curved substrate in Ex. 16.

### DETAILED DESCRIPTION

The present invention may be understood more readily by reference to the following detailed description of the invention taken in connection with the accompanying drawing figures, which form a part of this disclosure. It is to be understood that this invention is not limited to the specific devices, methods, conditions, or parameters described and/or shown herein, and that the terminology used herein is for the purpose of describing particular embodiments by way of example only and is not intended to be limiting of the claimed invention. Any and all patents and other publications identified in this specification are incorporated by reference as though fully set forth herein.

Also, as used in the specification, including the appended claims, the singular forms “a,” “an,” and “the” include the plural, and reference to a particular numerical value includes at least that particular value, unless the context clearly dictates otherwise. Ranges may be expressed herein as from “about” or “approximately” one particular value and/or to “about” or “approximately” another particular value. When such a range is expressed, another embodiment includes from the one particular value and/or to the other particular value. Similarly, when values are expressed as approximations, by use of the antecedent “about,” it will be understood that the particular value forms another embodiment.

It is to be understood that the mention of one or more method steps does not preclude the presence of additional method steps before or after the combined recited steps or intervening method steps between those steps expressly identified. Moreover, the lettering of method steps or ingredients is a conventional means for identifying discrete activities or ingredients, and the recited lettering can be arranged in any sequence, unless otherwise indicated.

As used herein, the term “and/or”, when used in a list of two or more items, means that any one of the listed items can be employed by itself, or any combination of two or more of the listed items can be employed. For example, if a composition is described as containing compounds A, B, “and/or” C, the composition may contain A alone; B alone; C alone; A and B in combination; A and C in combination; B and C in combination; or A, B, and C in combination.

As used herein, the term “array” refers to a set of multiple “organometallic deposits.” The “organometallic deposits” can all be in one layer, or the array can comprise multiple layers of “organometallic deposits.”

As used herein, the term “organometallic deposit” refers to a continuous, solid that has been deposited in a micro or nano dimension. An “organometallic deposit” can comprise a “wire.” As used herein, the term “wire” refers to an “organometallic deposit” or a section of an “organometallic deposit” that is linear and has a consistent width and height along its length. An “organometallic deposit” can comprise a “shape.” As used herein, a “shape” is an organometallic deposit that is not linear and/or does not have a consistent width and/or height along its length. Non-limiting examples of “shapes” include curves, right angles, a section of the “organometallic deposit” with a wider width or height than another section of the “organometallic deposit.” An “organometallic deposit” can comprise a “functional unit.” As used herein, a “functional unit” is an “organometallic deposit” having an independent electrical, mechanical, or optical functionality. As used herein, the term “base unit” refers to an element of the “organometallic deposit.” Non-limiting examples of a “base unit” include a “wire”, a “shape”, and a “functional unit”. A single “organometallic deposit” can comprise any combination of “base units” such as wire, shape, and/or functional unit.

As used herein, the term “3D feature,” refers to a base unit that has a shape variation (width, length, curvature, angle, etc.) along the Z axis and/or has an aspect ratio (height to width and/or height to length) of no smaller than 3.

As used herein, the term “organometallic synthon” refers to an initial reaction product of a metal ion, an acid, and the solvent. As used herein, the term “organometallic adducts” refers to the formation product of two or more “organometallic synthons.”

As used herein, the term “hydrocarbyl group” refers to a mono-valent hydrocarbon group. “Hydrocarbyl group” includes groups such as alkyls, alkenes, alkynes, aryls, and cycloalkyls. The “hydrocarbyl group” may be substituted or unsubstituted, branched or straight chain, and saturated, mono-unsaturated, or poly-unsaturated.

As used herein, the term “axis of interest” refers to the positioning of a layer of “organometallic deposits.” The “axis of interest” for any two adjacent layers is different. At least a portion of the “organometallic deposits” on adjacent layers intersect.

In some aspects, the techniques described herein relate to a method for forming an array, the method including: (a) forming a layerₓ on a substrate, wherein x=1, the layerₓ is a layer₁, and the layer₁ is attached to the substrate. The forming of the layerₓ includes forming organometallic deposits. The forming of the organometallic deposits includes: (i) providing a solution to openings of channels; (ii) forming and pinning down organometallic adducts as the solution penetrates the channels; and (iii) evaporating at least a portion of the solution to form the organometallic deposits. The solution includes synthon metal ions, an acid, and a solvent. The solution is formed by etching metal particles with the acid and the solvent proximate the openings or feeding the solution through the openings. Each of the organometallic deposits includes a wire, a shape, and/or a functional unit, and each of the organometallic deposits has a micro and/or a nano dimension.

In some aspects, the method of forming an array further comprises: (b) forming a layer₍ₓ₊₁₎ adjacent to the layerₓ along an axis of interest; and (c) incrementing x by 1 and repeating step b) until a set number of layers is reached. In some aspects, the forming of each of the layer₍ₓ₊₁₎ comprises the forming of the organometallic deposits. In some aspects, the axis of interest of the layer₍ₓ₊₁₎ and the axis of interest of the layerₓ are different. In some aspects, the set number of layers is at least 2.

In some aspects, the metal particles comprise a transition metal, a p-block metal, a rare earth metal, a group I metal, and/or a group II metal.

In some aspects, the solvent comprises water, an alcohol, a ketone, an amine, an amide, and/or a thiol. In some aspects, the acid is represented by formula R X₁X₂X₃H, wherein R is a C₁-C₂₀ hydrocarbyl group; X₁ is C, N, or P; X₂ and X₃ are independently O, P, N, or S.

In some aspects, the substrate comprises a ceramic, a polymer, a metal, or glass. In some aspects, the substrate has a curved shape.

In some aspects, layer₁ comprises at least 50 organometallic deposits. In some aspects, an area of the array is at least 1 mm².

In some aspects, the array is capable of functioning as a metamaterial, a waveguide, a photonic diode, and/or a guided-mode resonance device.

In some aspects, the method of forming an array further comprises (d) calcining the layer₁ and/or at least one of the layer₍ₓ₊₁₎; and/or (e) plasma processing the layer₁ and/or at least one of the layer₍ₓ₊₁₎.

In some aspects, a difference between the axis of interest for each of the layerₓ and for each of the layer₍ₓ₊₁₎ varies between 5 degrees and 175 degrees.

In some aspects, on the layer₁ and each of the layer₍ₓ₊₁₎, at least a portion of the organometallic deposits have a height ranging from 1 nm to 10 μm, a width ranging from 20 nm to 100 μm, and a length ranging from 100 nm to 450 mm.

In some aspects, on the layer₁ or any of the layer₍ₓ₊₁₎, at least a portion of the organometallic deposits comprise a shape, and wherein the shape is selected from the group consisting of 2D manifestations of an angle, 3D manifestations of an angle, a curvature, a right angle corner, a zig-zag, a pattern of (i) departing from a fixed point, (ii) proceeding down a first length, (iii) returning to the fixed point, and proceeding down a second length, or a pattern comprising periodic functional units.

In some aspects, the shape of at least a portion of the organometallic deposits on a first layer selected from the layer₁ or the layer₍ₓ₊₁₎ and the shape of at least a portion of the organometallic deposits on a second layer selected from the layer₁ or the layer₍ₓ₊₁₎ is different.

In some aspects, on the layer₁ and each of the layer₍ₓ₊₁₎, a periodicity of at least a portion of the organometallic deposits ranges from 1 nm to 50 mm.

In some aspects, the layer₁ and any of the layer₍ₓ₊₁₎ has a 3D feature, wherein at least one of the organometallic deposits has a height greater than 10 μm to 100 μm along at least a portion of a length, or wherein at least two consecutive layers of the layer₁ or the one or more layer₍ₓ₊₁₎ in combination have a 3D feature.

In some aspects, the composition of at least one of the layer₁ or any of the layer₍ₓ₊₁₎ varies across the array.

In some aspects, the array comprises a light Guiding Component, a Phase & Wavefront Control Component, a Direction & Routing Component, a Filtering & Spectral Control Component, a Light Generation Component, a Detection Component, a Modulation Component, and/or a Resonant/Energy Storage Component.

In some aspects, the techniques described herein relate to a method for forming an array, the method including: (a) forming a layerₓ, (b) forming a layer₍ₓ₊₁₎ adjacent to the layerₓ along an axis of interest; and (c) incrementing x by 1 and repeating step b) until a set number of layers is reached. When x=1, the layerₓ is layer₁, and layer₁ is attached to a substrate. The forming of the layerₓ and of the layer₍ₓ₊₁₎ includes forming organometallic deposits. The axis of interest of the layer₍ₓ₊₁₎ and the axis of interest of the layerₓ are different. The forming of the organometallic deposits includes: (i) providing a solution to openings of channels; (ii) forming and pinning down organometallic adducts as the solution penetrates the channels; and (iii) evaporating at least a portion of the solution to form the organometallic deposits. The solution includes synthon metal ions, an acid, and a solvent. The solution is formed by etching metal particles with the acid and the solvent proximate the openings or feeding the solution through the openings. Each of the organometallic deposits includes a wire, a shape, and/or a functional unit, and each of the organometallic deposits has a micro and/or a nano dimension.

In some aspects, the metal particles comprise a transition metal, a p-block metal, a rare earth metal, a group I metal, and/or a group II metal. In some aspects, the solvent comprises water, an alcohol, a ketone, an amine, an amide, and/or a thiol. In some aspects, the acid is represented by the formula R X₁X₂X₃H, wherein R is a C₁-C₂₀ hydrocarbyl group; X₁ is C, N, or P ; X₂ and X₃ are independently O, P, N, or S.

In some aspects, the array is capable of functioning as a metamaterial, a waveguide, a photonic diode, and/or a guided-mode resonance device.

In some aspects, the techniques described herein relate to an array including at least one layer, wherein the at least one layer includes organometallic deposits. The organometallic deposits have a micro and/or a nano dimension, and the organometallic deposits include a wire, a shape, and/or a functional unit.

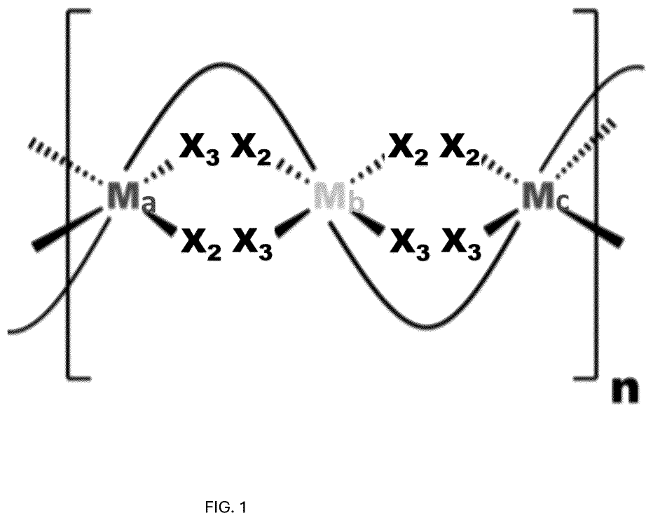

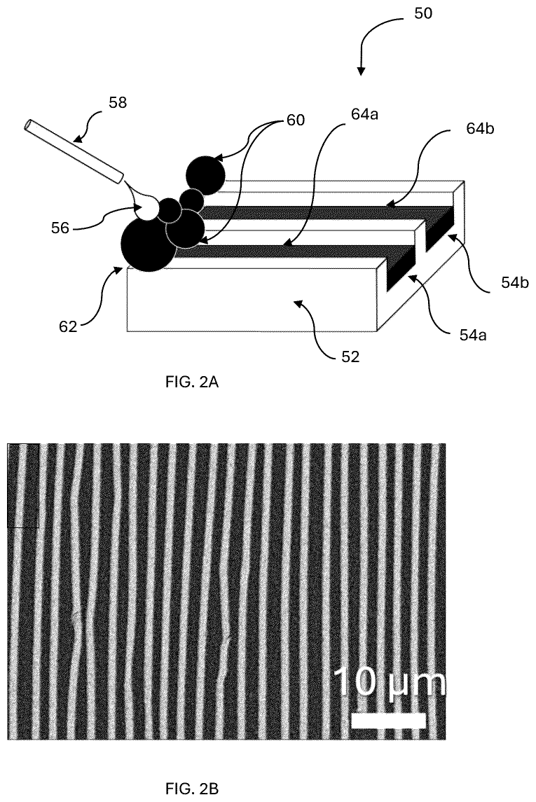

FIG. 1 is a schematic of an organometallic adduct showing metal ions, Mₐ, M_{b}, and M_{c}, which can be the same or different, interloping with the residual acid ligand. In some aspects, the acid is represented by the formula RX₁X₂X₃H. In some aspects R is a C₁-C₂₀ hydrocarbyl group. In some aspects, X₁ is C, N or P. In some aspects, X₂ and X₃ are independently O, P, N, or S. In some aspects, X₂ and X₃ are independently O, P, N, S, or OH. The acid, RX₁X₂X₃H ionizes and forms chelating and bridging bonds, connecting the metal ions Mₐ, M_{b}, and M_{c}. While the chelating ligand covalently bonds to the metal ions into a continuous loop structure, the bridging ligands are weakly-bonded or exposed groups.

In some aspects, the array is capable of functioning as a metamaterial, a waveguide, a photonic diode, and/or a guided-mode resonance device. In some aspects, the array is capable of functioning as a metamaterial, a waveguide, a photonic diode, and/or a guided-mode resonance device, wherein the metamaterial comprises an optical metamaterial and wherein the optical metamaterial comprises a metalens and/or surface relief grating. In some aspects, the array is capable of functioning as a diode, a transistor, a resistor, a capacitor, an inductor, a source, a switch, and/or an amplifier.

In some aspects, the array comprises a diode, a gate, a field-effect transistor (FET), a fin field-effect transistor (FinFET), a rectifier, and/or a computational device. In some aspects, the array comprises a light Guiding Component, a Phase & Wavefront Control Component, a Direction & Routing Component, a Filtering & Spectral Control Component, a Light Generation Component, a Detection Component, a Modulation Component, and/or a Resonant/Energy Storage Component. Non-limiting examples of a light Guiding Component include waveguides, fibers, and beam splitters/couplers. Non-limiting examples of a Phase & Wavefront Control Component include (meta)lens, metasurfaces, and phase shifters. Non-limiting examples of a Direction & Routing Component include a mirror and a grating. Non-limiting examples of a Filtering & Spectral Control Component include an optical filter and a polarizer. Non-limiting examples of a Light Generation Component include an LED. Non-limiting examples of a Detection Component include a photodiode.

In some aspects, a device comprises the array. In some aspects, the device is selected from the group consisting of an imaging device, a communication device, a Sensing & Measurement Device, a Computation & Processing Device, a Display Device, a Light Generation Device, an Industrial & Medical Device, a Scientific & Quantum Device, a Computer, a quantum computer, a Photonic Integrated Circuit, or an Optical Computing/AI System. Non-limiting examples of an imaging device include a camera, a microscope, and an AR/VR system. Non-limiting examples of a communication device include an optical transceiver. Non-limiting examples of a Sensing & Measurement Device include an LIDAR and a spectrometer. Non-limiting examples of a Computation & Processing Device include a Photonic processor, and an optical computer. Non-limiting examples of a Display Device include a screen, a projector, and a display. Non-limiting examples of a Light Generation Device include an LED and a Laser. Non-limiting examples of an Industrial & Medical Device include a Laser machining system and endoscopy equipment. Non-limiting examples of a Scientific & Quantum Device include an Interferometer and a Quantum photonic system.
Embodiment 1. A method of forming an organometallic deposit, the method comprising: (a) providing a solution to an opening of a channel; (b) forming and pinning down organometallic adducts as the solution penetrates the channel; and (c) evaporating at least a portion of the solution to form the organometallic deposit, wherein the solution comprises synthon metal ions, an acid, and a solvent; wherein the solution is formed by etching metal particles with the acid and the solvent proximate the opening or feeding the solution through the opening; wherein the organometallic deposit has a micro and/or a nano dimension, and wherein the organometallic deposit comprises a wire, a shape, and/or a functional unit.
Embodiment 2. The method of embodiment 1, further comprising: (d) subjecting the organometallic deposit to a post-processing step, wherein the post-processing step is selected from the group consisting of thermal processing in a reductive environment, thermal processing in an oxidative environment, plasma treatment in a reductive environment, or plasma treatment in an oxidative environment.
Embodiment 3. The method of any one of embodiments 1 or 2, wherein the channel has a width ranging from 1 nm to 10 μm, or from 50 nm to 10 μm, or from 200 nm to 10 μm, or from 500 nm to 10 μm, or from 1 μm to 10 μm, or from 3 μm to 10 μm, or from 5 μm to 10 μm; wherein the channel has a height ranging from 1 nm to 1 μm, or from 50 nm to 1 μm, or from 100 nm to 1 μm, or from 200 nm to 1 μm, or from 500 nm to 1 μm; and/or wherein the channel has a length ranging from 100 nm to 20 mm.
Embodiment 4. The method of any one of embodiments 1-3, wherein the metal particles comprise a transition metal, a p-block metal, a rare earth metal, a group I metal, and/or a group II metal; or wherein the metal particles comprise a transition metal, a p-block metal, and/or a rare earth metal; or wherein the metal particles comprise a p-block metal; or wherein the metal particles comprise Field's metal, In, Sn, and/or Bi.
Embodiment 5. The method of any one of embodiments 1 or 4, wherein the acid is represented by formula RX₁X₂X₃H, wherein R is a C1-C20 hydrocarbyl group, X₁ is C, N or P ; X₂ and X₃ are independently O, P, N, or S; or wherein the acid is represented by formula RX₁X₂X₃H, wherein R is a C1-C20 hydrocarbyl group, X₁ is C, N, or P; and X₂ and X₃ are independently O, P, N, S, or OH; wherein the acid comprises a carboxylic acid, acetic acid, stearic acid, benzoic acid, butyric acid, butanoic acid, adipic acid, malonic acid, muconic acid, an amino acid (e.g., one or more of praline, arginine, histidine, alanine, tryptophan, glutamic acid, cysteine, and structural analogs thereof), or a combination thereof; or wherein the acid comprises a carboxylic acid; or wherein the acid comprises acetic acid.
Embodiment 6. The method of any one of embodiments 1-5, wherein the solvent is polar; or wherein the solvent is non-polar; or wherein the solvent comprises water, an alcohol, a ketone, an amine, an amide, and/or a thiol; or wherein the solvent comprises water, acetone, and/or ethanol.
Embodiment 7. The method of any one of embodiments 1-6, wherein each of the organometallic deposits has a height ranging from 10 nm to 10 μm, a width ranging from 20 nm to 100 μm, and a length ranging from 100 nm to 450 mm, or 100 nm to 300 mm, or 100 nm to 150 mm, or 100 nm to 75 mm, or 100 nm to 50 mm, or 100 nm to 25 mm, or 100 nm to 15 mm; or wherein each of the organometallic deposits has a height ranging from 1 nm to 10 μm, a width ranging from 20 nm to 100 μm, and a length ranging from 100 nm to 450 mm, or 100 nm to 300 mm, or 100 nm to 150 mm, or 100 nm to 75 mm, or 100 nm to 50 mm, or 100 nm to 25 mm, or 100 nm to 15 mm.
Embodiment 8. The method of any one of embodiments 1-7, wherein the organometallic deposit comprises a shape; or wherein at least a portion of the organometallic deposit comprises a shape, and wherein the shape includes both 2D and 3D manifestations of an angle, a curvature, a right angle corner, a zig-zag, a pattern of (i) departing from a fixed point, (ii) proceeding down a first length, (iii) returning to the fixed point, and proceeding down a second length, and/or a pattern comprising periodic functional units (such as a micro-rotor mimicking design).
Embodiment 9. The method of any one of embodiments 1-8, wherein the organometallic deposit has a 3D feature, wherein the organometallic deposit has a height ranging from greater than 10 μm to 100 μm along at least a portion of a length.
Embodiment 10. The method of any of embodiments 1-9, wherein the channel is fluidly connected to a substrate, wherein the organometallic deposit is attached to the substrate, and wherein the substrate comprises a ceramic, a polymer, a metal, or glass; or wherein the substrate comprises a ceramic, a polymer, a metal, or glass and the ceramic comprises silicon, GaN, sapphire, and/or a metal oxide, the polymer comprises polyethylene, PMMA, and/or PTFE, or the metal comprises gold, silver, and/or platinum; or wherein the substrate comprises a computer chip, a diode, a gate, a field-effect transistor (FET), a fin field-effect transistor (FinFET), a rectifier, and/or a computational device; or wherein the substrate comprises a light Guiding Component, a Phase & Wavefront Control Component, a Direction & Routing Component, a Filtering & Spectral Control Component, a Light Generation Component, a Detection Component, a Modulation Component, and/or a Resonant/Energy Storage Component.
Embodiment 11. The method of embodiment 10, wherein the substrate has a curved shape; or wherein an edge of the substrate is curved (as in a disc, semicircle, etc.); or wherein the substrate has a varying height (as in higher in the center of the substrate than at the edge of the substrate); or wherein the substrate has a 3D curved shape as the edge of the substrate is curved and the substrate has the varying height.
Embodiment 12. The method of any of embodiments 1-11, wherein at least a portion of the solution that evaporates leaves the channel through an exit distal to the opening; or wherein the channel is closed along its length, and wherein at least a portion of the solution that evaporates leaves the channel through an exit distal to the opening.
Embodiment 13. The method of any of embodiments 1-12, wherein a mold comprises the channel, wherein the mold comprises a polymer; or wherein a mold comprises the channel, and wherein the mold comprises polydimethylsiloxane (PDMS), an epoxy-based photoresist, and/or an epoxy.
Embodiment 14. The method of any one of embodiments 1-13, wherein the method is performed using a microfluidic system for a continuous growth and formation of the organometallic deposit.
Embodiment 15. The method of any one of embodiments 1-14, wherein a multiple of the organometallic deposits are formed into an array.
Embodiment 16. The method of embodiment 15, wherein the organometallic adducts are reduced into graphitic or related 2D materials, and wherein the graphitic or related 2D materials intercalate into a structure of the array.
Embodiment 17. The method of any one of embodiments 1-16, wherein the organometallic deposit has a catalytic property; or wherein the organometallic deposit has a catalytic property, and wherein the catalytic property of the organometallic deposit varies over a length of the organometallic deposit.
Embodiment 18. The method of any one of embodiments 1-17, wherein the organometallic deposit comprises a diode, a gate, a field-effect transistor (FET), a fin field-effect transistor (FinFET), a rectifier, and/or a computational device; or wherein the organometallic deposit comprises a light Guiding Component, a Phase & Wavefront Control Component, a Direction & Routing Component, a Filtering & Spectral Control Component, a Light Generation Component, a Detection Component, a Modulation Component, and/or a Resonant/Energy Storage Component; or wherein the organometallic deposit a light guiding component, a phase & wavefront control component, a light direction & routing component, a filtering & spectral control component, a light generation component, a detection component, a modulation component, a resonant component, an energy storage component, a junction, a diode, a transistor, a resistor, a capacitor, an inductor, a source, a switch, an amplifier, and/or a catalyst.
Embodiment 19. A method for forming an array, the method comprising: (a) forming a layerₓ on a substrate, wherein x=1, wherein a layer₁ comprises organometallic deposits, wherein each of the organometallic deposits comprises a wire, a shape, and/or a functional unit, and wherein each of the organometallic deposits has a micro and/or a nano dimension.
Embodiment 20. The method of embodiment 19, further comprising: (b) forming a layer₍ₓ₊₁₎ adjacent to the layerₓ along an axis of interest; and (c) incrementing x by 1 and repeating step b) until a set number of layers is reached, wherein each of the layer₍ₓ₊₁₎ comprises the organometallic deposits, wherein the axis of interest of the layer₍ₓ₊₁₎ and the axis of interest of the layerₓ are different, and wherein the set number of layers is at least 2.
Embodiment 21. The method of any one of embodiments 19 or 20, wherein the organometallic deposits are formed by the method of any one of the embodiments 1-18.
Embodiment 22. The method of any one of embodiments 19-21, wherein each of the organometallic deposits is independently selected for the layer₁ and each of the layer₍ₓ₊₁₎; or wherein each of the organometallic deposits is substantially identical for the layer₁ and each of the layer₍ₓ₊₁₎.
Embodiment 23. The method of any one of embodiments 19-22, wherein each of the layer₁ and each of the layer₍ₓ₊₁₎ comprises at least 50, or at least 100, or at least 500, or at least 1,000, or at least 10,000 organometallic deposits; or wherein each of the layer₁ and each of the layer₍ₓ₊₁₎ comprises 50 to 10 M, or 50 to 100 M of the organometallic deposits.
Embodiment 24. The method of any one of embodiments 19-23, wherein on the layer₁ and each of the layer₍ₓ₊₁₎ at least a portion of the organometallic deposits have a height ranging from 10 nm to 10 μm, a width ranging from 20 nm to 100 μm, and a length ranging from 100 nm to 450 mm, or 100 nm to 300 mm, or 100 nm to 150 mm, or 100 nm to 75 mm, or 100 nm to 50 mm, or 100 nm to 25 mm, or 100 nm to 15 mm.
Embodiment 25. The method of any one of embodiments 19-24, wherein on the layer₁ and each of the layer₍ₓ₊₁₎ the organometallic deposits are made by etching metal particles proximate to a channel opening, or by feeding a solution containing synthon metal ions to the channel opening.
Embodiment 26. The method of any one of embodiments 19-25, wherein at least a portion of the organometallic deposits comprise a shape; or wherein at least a portion of the organometallic deposits comprise a shape, and wherein the shape includes both 2D and 3D manifestations of an angle, a curvature, a right angle corner, a zig-zag, a pattern of (i) departing from a fixed point, (ii) proceeding down a first length, (iii) returning to the fixed point, and proceeding down a second length, and/or a pattern comprising periodic functional units (such as a micro-rotor mimicking design).
Embodiment 27. The method of any one of embodiments 19-26, wherein an area of the array is at least 1 mm², or at least 5 mm², or at least 10 mm², or at least 50 mm², or at least 100 mm₂, or at least 250 mm², or at least 500 mm², or at least 750 mm², or at least 1,000 mm²; or wherein an area of the array ranges from 1 mm² to 1,000 mm², or from 1 mm² to 750 mm², or from 1 mm² to 500 mm², or from 1 mm² to 250 mm², or from 1 mm² to 1000 mm², or from 1 mm² to 50 mm², or from 1 mm² to 25 mm², or from 1 mm² to 10 mm², or from 1 mm² to 5 mm².
Embodiment 28. The method of any one of embodiments 19-27, wherein on the layer₁ and each of the layer₍ₓ₊₁₎ a periodicity of the organometallic deposits ranges from 10 nm to 50 mm, or from 10 nm to 1 mm, or from 10 nm to 1000 μm, or from 10 nm to 500 μm, or from 10 nm to 100 μm, or from 10 nm to 50 μm, or from 10 nm to 10 μm, or from 10 nm to 2 μm, or from 40 nm to 1 mm; or wherein on the layer1 and each of the layer₍ₓ₊₁₎ a periodicity of the organometallic deposits ranges from 1 nm to 50 mm, or from 1 nm to 1 mm, or from 1 nm to 1000 μm, or from 1 nm to 500 μm, or from 1 nm to 100 μm, or from 1 nm to 50 μm, or from 1 nm to 10 μm, or from 1 nm to 2 μm, or from 1 nm to 1 μm.
Embodiment 29. The method of any one of embodiments 19-28, wherein the substrate comprises a ceramic, a polymer, a metal, or glass; or wherein the substrate comprises a ceramic, a polymer, a metal, or glass, and the ceramic comprises silicon, GaN, sapphire, and/or a metal oxide, the polymer comprises polyethylene, PMMA, and/or PTFE, or the metal comprises gold, silver, and/or platinum; or wherein the substrate comprises a computer chip, a diode, a gate, a field-effect transistor (FET), a fin field-effect transistor (FinFET), a rectifier, and/or a computational device; or wherein the substrate comprises a light Guiding Component, a Phase & Wavefront Control Component, a Direction & Routing Component, a Filtering & Spectral Control Component, a Light Generation Component, a Detection Component, a Modulation Component, and/or a Resonant/Energy Storage Component; or wherein the substrate comprises a light guiding component, a phase & wavefront control component, a light direction & routing component, a filtering & spectral control component, a light generation component, a detection component, a modulation component, a resonant component, an energy storage component, a junction, a diode, a transistor, a resistor, a capacitor, an inductor, a source, a switch, an amplifier, and/or a catalyst.
Embodiment 30. The method of any one of embodiments 19-29, wherein the substrate has a curved shape; or wherein an edge of the substrate is curved (as in a disc, semicircle, etc.); or wherein the substrate has a varying height (as in higher in the center of the substrate than at the edge of the substrate); or wherein the substrate has a 3D curved shape as the edge of the substrate is curved and the substrate has the varying height.
Embodiment 31. The method of any one of embodiments 19-30, wherein the array is capable of functioning as a metamaterial, a waveguide, a photonic diode, and/or a guided-mode resonance device; or wherein the array is capable of functioning as a metamaterial, a waveguide, a photonic diode, and/or a guided-mode resonance device, wherein the metamaterial comprises an optical metamaterial and wherein the optical metamaterial comprises a metalens and/or surface relief grating; or wherein the array is capable of functioning as a diode, a transistor, a resistor, a capacitor, an inductor, a source, a switch, and/or an amplifier; or wherein the array is capable of functioning as a light guiding component, a phase & wavefront control component, a light direction & routing component, a filtering & spectral control component, a light generation component, a detection component, a modulation component, a resonant component, an energy storage component, a junction, a diode, a transistor, a resistor, a capacitor, an inductor, a source, a switch, an amplifier, and/or a catalyst.
Embodiment 32. The method of any one of embodiments 20-31, wherein a difference between the axis of interest for each of the layerₓ and for each of the layer₍ₓ₊₁₎ varies between 0.5 degrees and 179.5 degrees, or between 1 degree and 179 degrees, or between 5 degrees and 175 degrees or between 20 degrees and 160 degrees, or between 45 degrees and 135 degrees; or wherein the axis of interest for each of the layerₓ is 90 degrees different than the axis of interest for each of the layer₍ₓ₊₁₎.
Embodiment 33. The method of any one of embodiments 19-32, wherein at least one of the layer₁ and/or the one or more layer₍ₓ₊₁₎ has a 3D feature, wherein at least one of the organometallic deposits has a height greater than 10 μm to 100 μm along at least a portion of a length, or wherein at least two consecutive layers of the layer1 or the one or more layer₍ₓ₊₁₎ in combination has a 3D feature.
Embodiment 34. The method of any one of embodiments 19-33, wherein a composition of each of the layer₁ or the one or more layer₍ₓ₊₁₎ is uniform throughout the each of the layer₁ or the one or more layer₍ₓ₊₁₎; or wherein a composition of at least one of the layer₁ or the one or more layer₍ₓ₊₁₎ varies across the array; or wherein a composition of at least one of the organometallic deposits varies along a length of the at least one of the organometallic deposits.
Embodiment 35. The method of any one of embodiments 19-34, wherein at least a first of the layer₁ and one or more layer₍ₓ₊₁₎ has a first composition, and at least a second of the layer₁ or the one or more layer₍ₓ₊₁₎ has a second composition, and the first composition and the second composition are different.
Embodiment 36. The method of any one of embodiments 19-35, further comprising: (d) calcining the layer₁ and/or at least one of the layer₍ₓ₊₁₎.
Embodiment 37. The method of any one of embodiments 19-36, wherein further comprising: (e) plasma processing the layer₁ and/or at least one of the layer₍ₓ₊₁₎.
Embodiment 38. The method of any one of embodiments 19-37, wherein the array functions as a catalyst; wherein the array has a catalytic property; or wherein the array has a catalytic property, and wherein the catalytic property of the array varies over a direction of the array.
Embodiment 39. The method of any one of embodiments 19-38, wherein the array comprises a diode, a gate, a field-effect transistor (FET), a fin field-effect transistor (FinFET), a rectifier, and/or a computational device; or wherein the array comprises a light Guiding Component, a Phase & Wavefront Control Component, a Direction & Routing Component, a Filtering & Spectral Control Component, a Light Generation Component, a Detection Component, a Modulation Component, and/or a Resonant/Energy Storage Component or wherein the array comprises a light guiding component, a phase & wavefront control component, a light direction & routing component, a filtering & spectral control component, a light generation component, a detection component, a modulation component, a resonant component, an energy storage component, a junction, a diode, a transistor, a resistor, a capacitor, an inductor, a source, a switch, an amplifier, and/or a catalyst; or wherein the array comprises a light guiding component, a phase & wavefront control component, a light direction & routing component, a filtering & spectral control component, a light generation component, a detection component, a modulation component, a resonant component, an energy storage component, a junction, a diode, a transistor, a resistor, a capacitor, an inductor, a source, a switch, an amplifier, and/or a catalyst.
Embodiment 40. A method of isolating a functional unit from the array formed in any of embodiments 20-35, further comprising: (d) removing a section of the array, wherein the section of the array comprises the functional unit.
Embodiment 41. An array comprising at least one layer, wherein the at least one layer comprises organometallic deposits, wherein the organometallic deposits have a micro and/or a nano dimension, and wherein the organometallic deposits comprise a wire, a shape, and/or a functional unit.
Embodiment 42. The array of embodiment 41, wherein the at least one layer comprises a number of the at least one layer greater than 1, greater than 5, greater than 10, greater than 50, or greater than 100.
Embodiment 43. The array of any one of embodiments 41 or 42, wherein the at least one layer comprises at least 50, or at least 100, or at least 500, or at least 1,000, or at least 10,000 organometallic deposits; or wherein the at least one layer comprises 50 to 10 M, or 50 to 100 M of the organometallic deposits.
Embodiment 44. The array of any one of embodiments 41-43, wherein the organometallic deposits comprise a metal ion, and where the metal ion comprises a transition metal ion, a p-block metal ion, a rare earth metal ion, a group I metal ion, and/or a group II metal ion; or wherein the metal ion comprises a transition metal ion, a p-block metal ion, and/or a rare earth metal ion; or wherein the metal ion comprises a p-block metal ion; or wherein the metal ion comprises an In ion, a Sn ion, and/or a Bi ion.
Embodiment 45. The array of any one of embodiments 41-44, wherein the organometallic deposits comprise residuals of an acid, and wherein the acid is represented by formula RX₁X₂X₃H, wherein R is a C₁-C₂₀ hydrocarbyl group, X₁ is C, N, or P, X₂ and X₃ are independently O, P, N, or S; or wherein the acid is represented by formula RX₁X₂X₃H, wherein R is a C₁-C₂₀ hydrocarbyl group, X₁ is C, N, or P, t X₂ and X₃ are independently O, P, N, S, or OH; or wherein the acid comprises a carboxylic acid, acetic acid, stearic acid, benzoic acid, butyric acid, butanoic acid, adipic acid, malonic acid, muconic acid, an amino acid (e.g., one or more of praline, arginine, histidine, alanine, tryptophan, glutamic acid, cysteine, and structural analogs thereof), or a combination thereof; or wherein the acid comprises a carboxylic acid; or wherein the acid comprises acetic acid.
Embodiment 46. The array of any one of embodiments 41-45, wherein each of the organometallic deposits has a height ranging from 10 nm to 10 μm, a width ranging from 20 nm to 100 μm, and a length ranging from 100 nm to 450 mm, or 100 nm to 300 mm, or 100 nm to 150 mm, or 100 nm to 75 mm, or 100 nm to 50 mm, or 100 nm to 25 mm, or 100 nm to 15 mm; or wherein the organometallic deposits have a height ranging from 1 nm to 10 μm, a width ranging from 20 nm to 100 μm, and a length ranging from 100 nm to 450 mm, or 100 nm to 300 mm, or 100 nm to 150 mm, or 100 nm to 75 mm, or 100 nm to 50 mm, or 100 nm to 25 mm, or 100 nm to 15 mm.
Embodiment 47. The array of any one of embodiments 41-46, wherein the organometallic deposits comprise a shape; or wherein at least a portion of the organometallic deposits comprises a shape, and wherein the shape includes both 2D and 3D manifestations of an angle, a curvature, a right angle corner, a zig-zag, a pattern of (i) departing from a fixed point, (ii) proceeding down a first length, (iii) returning to the fixed point, and proceeding down a second length, and/or a pattern comprising periodic functional units (such as a micro-rotor mimicking design).
Embodiment 48. The array of any one of embodiments 41-47, wherein at least one of the organometallic deposits has a 3D feature, wherein the at least one of the organometallic deposits has a height ranging from greater than 10 μm to 100 μm along at least a portion of a length.
Embodiment 49. The array of any one of embodiments 41-48, wherein at least a portion of the organometallic deposits comprise a shape; or wherein at least a portion of the organometallic deposits comprise a shape, and wherein the shape includes both 2D and 3D manifestations of an angle, a curvature, a right angle corner, a zig-zag, a pattern of (i) departing from a fixed point, (ii) proceeding down a first length, (iii) returning to the fixed point, and proceeding down a second length, and/or a pattern comprising periodic functional units (such as a micro-rotor mimicking design).
Embodiment 50. The array of any one of embodiments 41-49, wherein a first layer of the array is connected to a substrate, and wherein the substrate comprises a ceramic, a polymer, a metal, or glass; or wherein a first layer of the array is connected to a substrate and wherein the substrate comprises a ceramic, a polymer, a metal, or glass and the ceramic comprises silicon, GaN, sapphire, and/or a metal oxide, the polymer comprises polyethylene, PMMA, and/or PTFE, or the metal comprises gold, silver, and/or platinum; or wherein a first layer of the array is connected to a substrate and wherein the substrate comprises a computer chip, a diode, a gate, a field-effect transistor (FET), a fin field-effect transistor (FinFET), a rectifier, and/or a computational device; or wherein the substrate comprises a light Guiding Component, a Phase & Wavefront Control Component, a Direction & Routing Component, a Filtering & Spectral Control Component, a Light Generation Component, a Detection Component, a Modulation Component, and/or a Resonant/Energy Storage Component; or wherein the substrate comprises a light guiding component, a phase & wavefront control component, a light direction & routing component, a filtering & spectral control component, a light generation component, a detection component, a modulation component, a resonant component, an energy storage component, a junction, a diode, a transistor, a resistor, a capacitor, an inductor, a source, a switch, an amplifier, and/or a catalyst.
Embodiment 51. The array of embodiment 50, wherein the substrate has a curved shape; or wherein an edge of the substrate is curved (as in a disc, semicircle, etc.); or wherein the substrate has a varying height (as in higher in the center of the substrate than at the edge of the substrate); or wherein the substrate has a 3D curved shape as the edge of the substrate is curved and the substrate has the varying height.
Embodiment 52. The array of any one of embodiments 41-51, wherein the at least one layer comprises a first layer and a second layer; wherein the first layer and the second layer are adjacent; wherein the first layer comprises first organometallic deposits and the second layer comprises second organometallic deposits; and wherein at least a portion of the first organometallic deposits are intermittently connected to at least a portion of the second organometallic deposits.
Embodiment 53. The array of any one of embodiments 41-52, wherein an area of the array is at least 1 mm², or at least 5 mm², or at least 10 mm², or at least 50 mm², or at least 100 mm², or at least 250 mm², or at least 500 mm², or at least 750 mm², or at least 1,000 mm²; or wherein an area of the array ranges from 1 mm² to 1,000 mm², or from 1 mm² to 750 mm², or from 1 mm² to 500 mm², or from 1 mm² to 250 mm², or from 1 mm² to 1000 mm², or from 1 mm² to 50 mm², or from 1 mm² to 25 mm², or from 1 mm² to 10 mm², or from 1 mm² to 5 mm².
Embodiment 54. The array of any one of embodiments 41-53 wherein each of the at least one layer has a periodicity of the organometallic deposits and the periodicity of the organometallic deposits ranges from 10 nm to 50 mm, or from 10 nm to 1 mm, or from 10 nm to 1000 μm, or from 10 nm to 500 μm, or from 10 nm to 100 μm, or from 10 nm to 50 μm, or from 10 nm to 10 μm, or from 10 nm to 2 μm, or from 10 nm to 1 μm; or wherein each of the at least one layer has a periodicity of the organometallic deposits ranging from 1 nm to 50 mm, or from 1 nm to 1 mm, or from 1 nm to 1000 μm, or from 1 nm to 500 μm, or from 1 nm to 100 μm, or from 1 nm to 50 μm, or from 1 nm to 10 μm, or from 1 nm to 2 μm, or from 1 nm to 1 μm.
Embodiment 55. The array of any one of embodiments 41-54, wherein the array comprises a diode, a gate, a field-effect transistor (FET), a fin field-effect transistor (FinFET), a rectifier, and/or a computational device; or wherein the array comprises a light Guiding Component, a Phase & Wavefront Control Component, a Direction & Routing Component, a Filtering & Spectral Control Component, a Light Generation Component, a Detection Component, a Modulation Component, and/or a Resonant/Energy Storage Component; or wherein the array comprises a light guiding component, a phase & wavefront control component, a light direction & routing component, a filtering & spectral control component, a light generation component, a detection component, a modulation component, a resonant component, an energy storage component, a junction, a diode, a transistor, a resistor, a capacitor, an inductor, a source, a switch, an amplifier, and/or a catalyst.
Embodiment 56. The array of any one of embodiments 41-55, wherein at least one of the at least one layers has a 3D feature, wherein at least one of the organometallic deposits has a height greater than 10 μm to 100 μm along at least a portion of a length, and/or wherein at least two consecutive layers in combination have a 3D feature.
Embodiment 57. The array of any one of embodiments 41-56, wherein each of the at least one layer has a uniform composition; wherein a composition of at least one of the at least one layer has a non-uniform composition; or wherein a composition of at least one of the organometallic deposits varies along a length of the at least one of the organometallic deposits.
Embodiment 58. The array of any one of embodiments 41-57, wherein the array comprises a 3D manifestation of an angle with a blaze angle ranging from 1 degree to 75 degrees, or from 1 degree to 70 degrees, or from 1 degree to 60 degrees, or from 1 degree to 50 degrees, or from 1 degree to 40 degrees, or from 1 degree to 30 degrees, or from 1 degree to 20 degrees, or from 5 degrees to 75 degrees, or from 5 degreed to 70 degrees, or from 5 degrees to 60 degrees, or from 5 degrees to 50 degrees, or from 5 degrees to 40 degrees, or from 5 degrees to 30 degrees, or from 5 degrees to 20 degrees, or from 10 degrees to 75 degrees, or from 10 degreed to 70 degrees, or from 10 degrees to 60 degrees, or from 10 degrees to 50 degrees, or from 10 degrees to 40 degrees, or from 10 degrees to 30 degrees, or from 10 degrees to 20 degrees.
Embodiment 59. A device comprising the array of any one of embodiments 41-58.
Embodiment 60. The device of embodiment 59, wherein the device is selected from the group consisting of an electrical diode, a photonic diode, a gate, a field-effect transistor (FET), a fin field-effect transistor (FinFET), Bilayer pseudoSpin Field-Effect Transistor (BiSFET), a rectifier, a guided-mode resonance device, a semiconductor component, a semiconductor, a transducer, a metalens, an optical wave guide, a Micro-Electro-Mechanical Sensor (MEMS) device, or a computational device; or wherein the device is selected from the group consisting of an imaging device, a communication device, a Sensing & Measurement Device, a Computation & Processing Device, a Display Device, a Light Generation Device, an Industrial & Medical Device, a Scientific & Quantum Device, a Computer, a quantum computer, a Photonic Integrated Circuit, or an Optical Computing/AI System.

### EXAMPLES

### Example 1—Synthesis of Undercooled Liquid Metal Core-shell Particles

Particles were synthesized as follows. For Field's metal particles, the metal (10 g) and diethylene glycol (200 mL) were placed in a Cuisinart® (SBC-1000FR) soup maker and heated to ca. 118° C. using the built-in base heater and heating tape wrapped around the soup maker jug. Then 2 mL of glacial acetic acid was added to the blender, and the mixture was sheared at ~9000 rpm (setting 2) for 10 minutes. The resulting suspension was quenched in ethanol and allowed to equilibrate to ambient conditions. The slurry was then filtered using a Buchner funnel with a Whatman GF/F filter. The filtered particles were washed with copious amounts of ethanol, followed by an ethyl acetate rinse. The remaining particles were then harvested and stored in ethyl acetate. For InSn particles, eutectic InSn alloy was made by mixing 10.20 g of indium metal into 12.05 g of molten tin, then the alloy was cooled down to room temperature. For particle synthesis, a mixture of 4.32 g of InSn alloy, 200 mL of diethylene glycol, and 1.04 g of trichloroacetic acid was preheated to 140° C. on a hot plate. Immediately after transferring the mixture to a tilted Cuisinart® (SBC-1000FR) soup maker, the mixture was sheared at a speed of ~17000 rpm (setting 4) for 4 minutes. Obtained particles were filtered following the same procedure as Field's metal particles.

### Example 2—Fabrication of Pristine Arrays-Open Channel

FIG. 2A is a perspective view of a schematic of the open channel process for making organometallic deposits (i.e., D-Met process). The mold 52 has two open channels 54a and 54b. The activation agent 56 is applied, using a pipet 58, to the metal particles 60 located at an entrance 62 of the mold 52. As the activation agent 56 etches the metal particles 60, the organometallic deposits 64a and 64b grow down the open channels 54a and 54b.

AcOH/Ace activation agent (comprising the acid and the base) applied in the D-Met process was prepared by mixing 5 mL of glacial acetic acid with 5 mL of acetone. An undercooled metal particle solution (ca. 1 μL) containing Field's metal particles was dropped on one end of a polydimethylsiloxane (PDMS) mold by micropipette. Then ~0.1 mL of the solution was deposited onto the deposited particle by pipette. The grating channels were filled by liquid automatically. The samples were kept in ambient for ~30 minutes until the solution dried completely. This flux-and-dry procedure was repeated two more times. Then a substrate (Si or glass) attached by two-sided carbon tape was placed onto the top of the PDMS mold. After picking the mold up with tweezers, the obtained wire array was transferred onto the substrate. FIG. 2B shows a micrograph of the wires (i.e., organometallic deposits) obtained in Example 2.

### Example 3—Fabrication of Pristine Arrays-Closed Channel

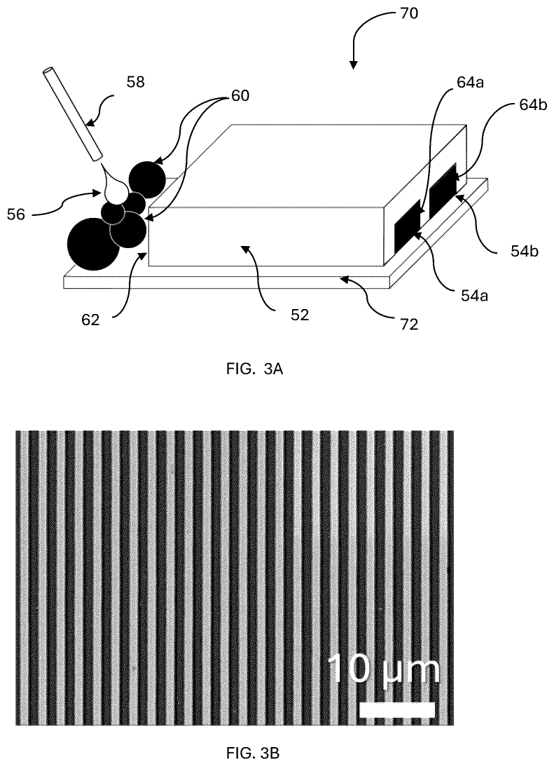

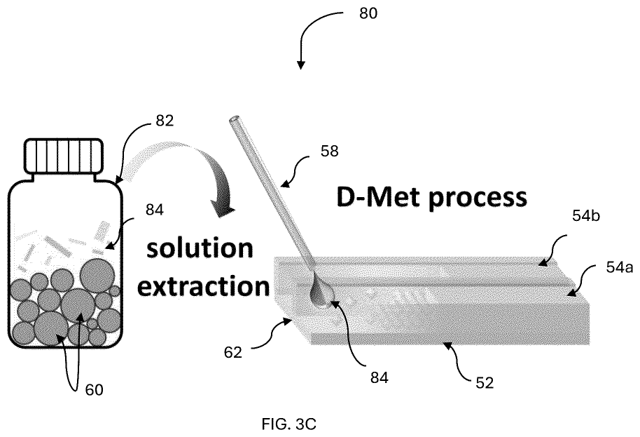

Example 2 was repeated except the mold was turned over and placed directly on a substrate. FIG. 3A is a perspective view of a schematic of the closed channel process 70 for making organometallic deposits 64a and 64b. The metal particles are placed on the substrate 72 near an entrance 62 of the mold 52. The activation agent 56 is applied, using a pipet 58, to the metal particles 60. As the activation agent 56 etches the metal particles 60, the organometallic deposits 64a and 64b grow down the open channels 54a and 54b. In the closed-channel process, the channels 54a and 54b are fluidly connected to the substrate 72.

Undercooled metal particle solution (ca. 1 μL) was deposited on substrates (Si or glass). Then the PDMS grating with channels facing down was put near the deposited particles. One droplet (0.1 mL) of activation agent was dropped onto particles and completely dried in ambient before two more flux-and-dry cycles were carried out. Then the template was removed with the array formed directly on the substrate and ready to use. Inducing coherence in the fluidic shear, evaporation, and associated Marangoni flow, the nucleation point is pinned to the edge of the channel (Taylor dispersion) hence uniform periodic wire arrays were obtained. By closing the channel (Ex. 3), the associated Reynolds number (Re) was significantly lowered (as compared to the open-channel process in Ex. 2), triggering laminar flow hence uniformity. In this configuration, the liquid-solid contact line was directly pinned on the substrate with the nucleate deposited in its vicinity. FIG. 3B shows a micrograph of the wires (i.e., organometallic deposits) obtained in Example 3.

When the D-Met reaction was performed directly on a PDMS mold, the direction of solvent evaporation and capillary action were perpendicular (referred to as open channel growth, FIG. 2A). Their high Reynolds number had turbulent flow inducing deformation and non-uniformity in the size of the wires. When the grating was flipped, however, evaporation and capillary action were aligned (referred to as closed channel growth, FIG. 3A). Considering its robustness in fabricating high-quality arrays, the closed channel method of Example 3 was repeated for the rest of the Examples.

FIG. 3C is a schematic showing an alternative embodiment for the process of forming organometallic deposits 80. Instead of placing the metal particles 60 near an entrance 62 to a mold 52, the metal particles 60 are mixed with the acid (not shown) and solvent (not shown) in a container 82. The solution 84, comprising the synthon metal ions, the acid, and the solvent, is fed near the entrance 62 to the mold 52. Otherwise, the process of forming organometallic deposits 80 in FIG. 3C is the same as the process of forming organometallic deposits 50 described in FIG. 3A.

### Example 4—Evaluation of Agents (Acid/Solvent) With Varying Vapor Pressure

Example 3 was repeated with two different agents and the Field's metal particles. Activation agent AcOH/EtOH and AcOH/H2O were prepared, following the same method given in Example 1, by replacing acetone with ethanol and deionized water, respectively.

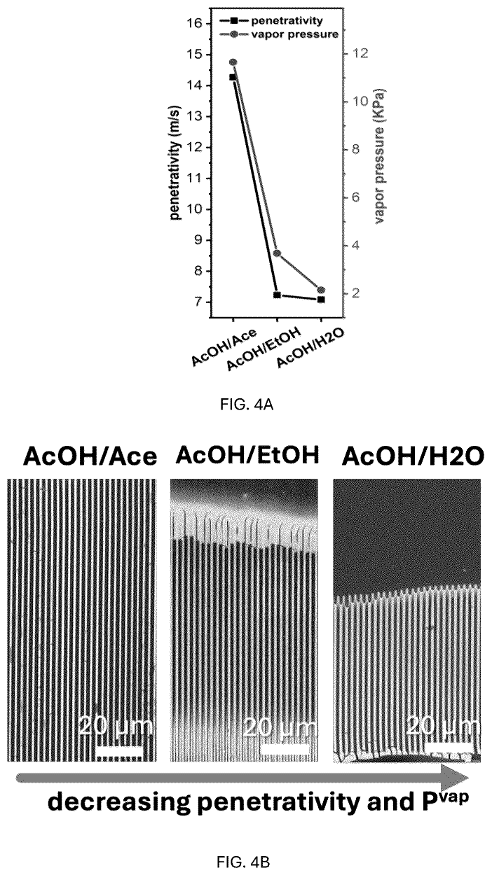

The obtained p value (m/s) is the speed of monomer-carrying solvents inside the channel. FIG. 4A gives a summary of corresponding penetrativity and vapor pressure (Pvap) for the solvent mixtures by treating the solutions as ideal binary liquids. As seen in FIG. 4A, penetrativity decreased with decreasing vapor pressure. FIG. 4B contains micrographs of the wires made using each of the three different agents. Wires generated with AcOH/Ace (Pvap=11.66 kPa) were the longest, albeit with significant amounts of defects along the length of the wires. In contrast, arrays generated with AcOH/EtOH (Pvap=3.68 kPa) had wires of moderate length and defect density. Arrays derived from AcOH/H2O (Pvap=2.15 kPa) were the shortest, albeit nearly defect-free. Higher penetrativity or Pvap gave longer but defective wires, which we infer to be due to non-uniform nucleation and growth. Thus, we inferred that a felicitous choice of solvent and fabrication conditions should give continuous and uniform morphology D-Met arrays. For the following Examples, ethanol was used as the standard solvent.

### Example 5—Formation of Pristine Arrays Made With Field's Metal Particles and Evaluation of Formation Zones and Different Wire Widths

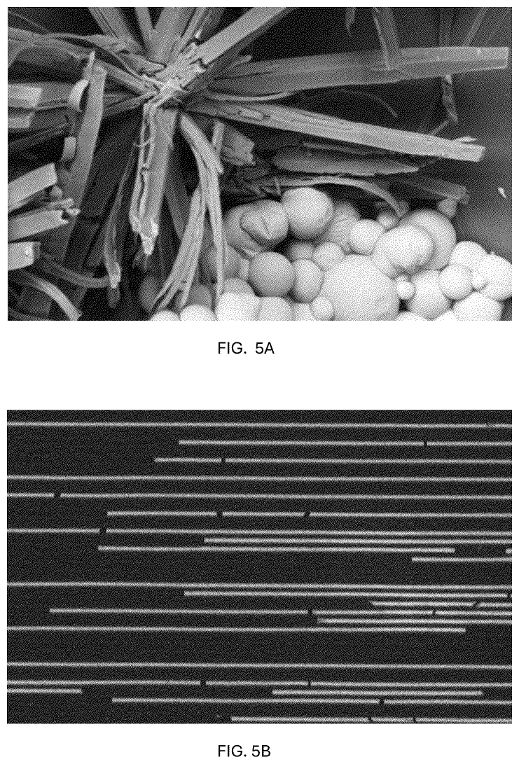

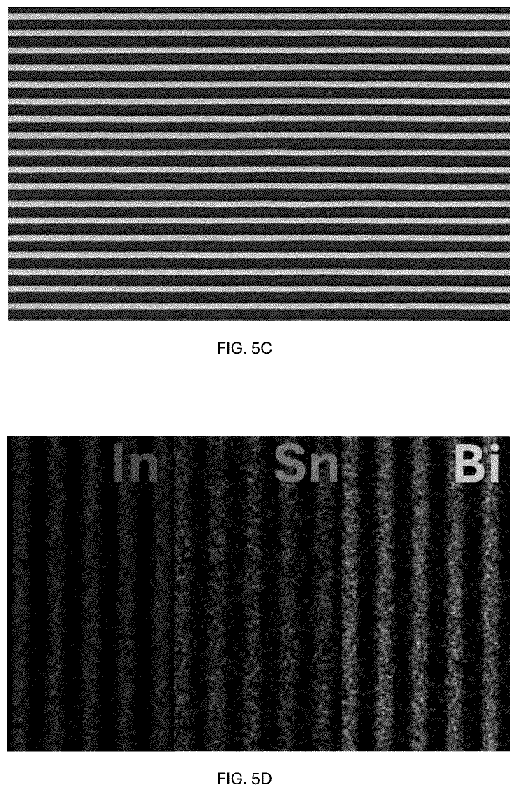

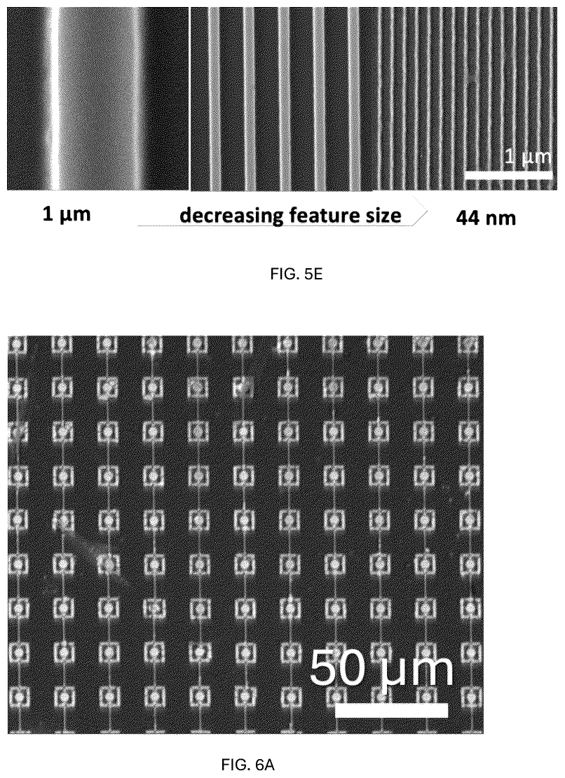

Example 3 was repeated with AcOH/EtOH as the activation agent and Field's metal particles. FIG. 5A is a micrograph of the dissolving zone, FIG. 5B is a micrograph of the growth zone, and FIG. 5C is a micrograph of the collection zone. FIG. 5A, dissolve zone, shows precipitation akin to Hetmet; FIG. 5B, growth zone, shows incomplete wire formation, and FIG. 5C, collection zone, shows wires that were fully formed. FIG. 5D shows an elemental mapping of the array. As seen in FIG. 5D, the undercooled Field's metal alloy particles showed a homogeneous distribution of three metal elements.

Example 3 was also repeated with channels of varying widths to produce wires of different widths. FIG. 5E shows micrographs of wires with three different widths. The wires were produced with widths ranging from 1 μm to 44 nm.

### Example 6—Formation of Arrays With Two-dimensional Patterns and Shapes

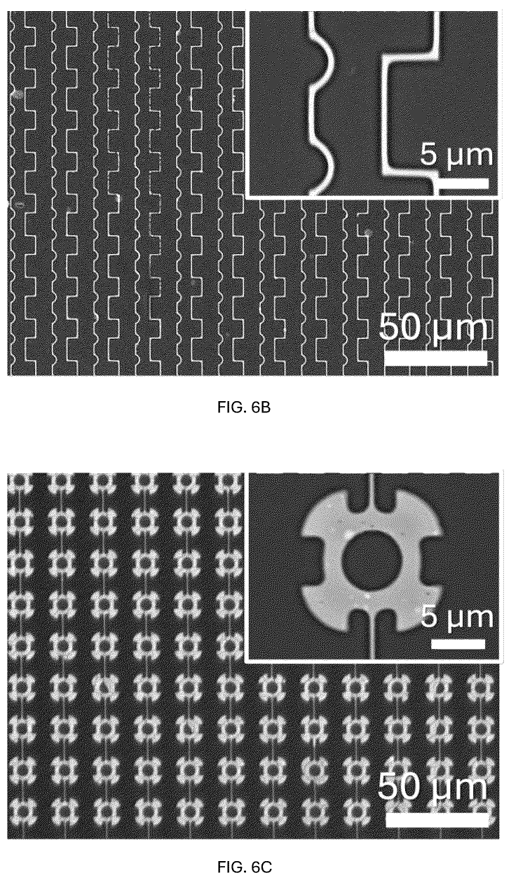

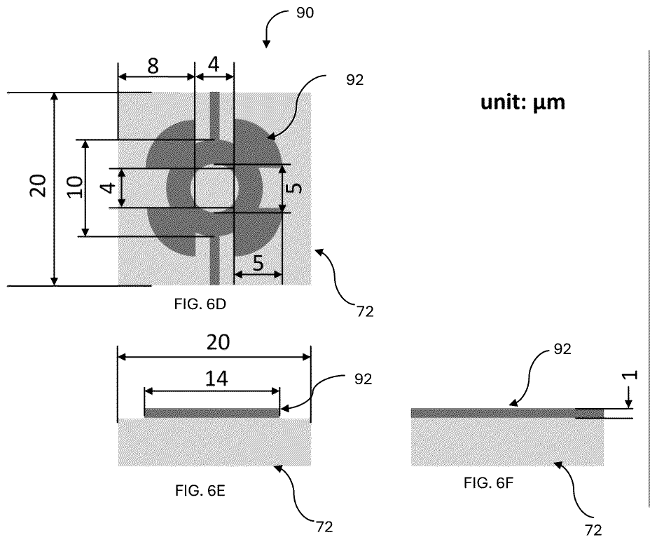

Example 5 was repeated using PDMS molds with complex pattern designs. FIG. 6A shows a micrograph of organometallic deposits with a complex pattern. Other deposition modifications of a single layer can be achieved through careful mold design and/or controlled fluid flow to enable generation of complex single layers. FIG. 6B shows a micrograph of an array of organometallic deposits in the form of a pattern with right-angle corners and curvatures. FIG. 6C is a micrograph of an array comprising a pattern of micro-rotor mimicking designs. This D-met approach can therefore be used to create structures analogous to current technologies.

FIGS. 6D, 6E, and 6F show top view, front view, and side view schematics, respectively, of a section 90 of the complex pattern shown in FIG. 6C. The section 90 shows one of the complex units 92 on a substrate 72. The measurements, shown in μm, give the dimensions of the different sections of the complex design.

### Example 7—Formation of Arrays With Three-dimensional Organometallic Deposits

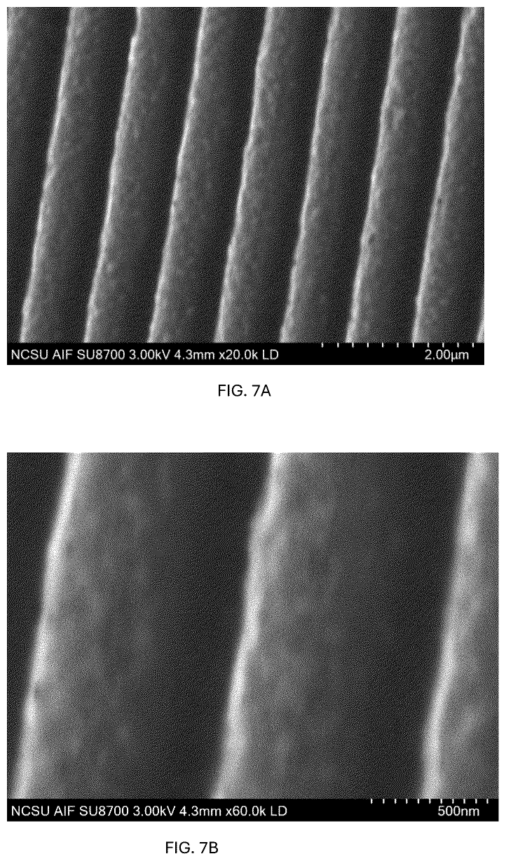

Arrays were formed using Field's metal particles as in Example 5, but with a different mold that facilitated the production of organometallic deposits with an angular 3D shape. The mold used had a groove density of 1200 grooves/mm and a blaze angle of 36.9°. FIG. 7A is a micrograph of the array of Ex. 7 at a magnification of 2 μm, and FIG. 7B is a micrograph of the array of Ex. 7 at a magnification of 500 nm. Being able to design arrays with organometallic deposits at different angles opens up the use of these arrays in a variety of optical applications.

### Example 8—Fabrication of 2-Layer Arrays

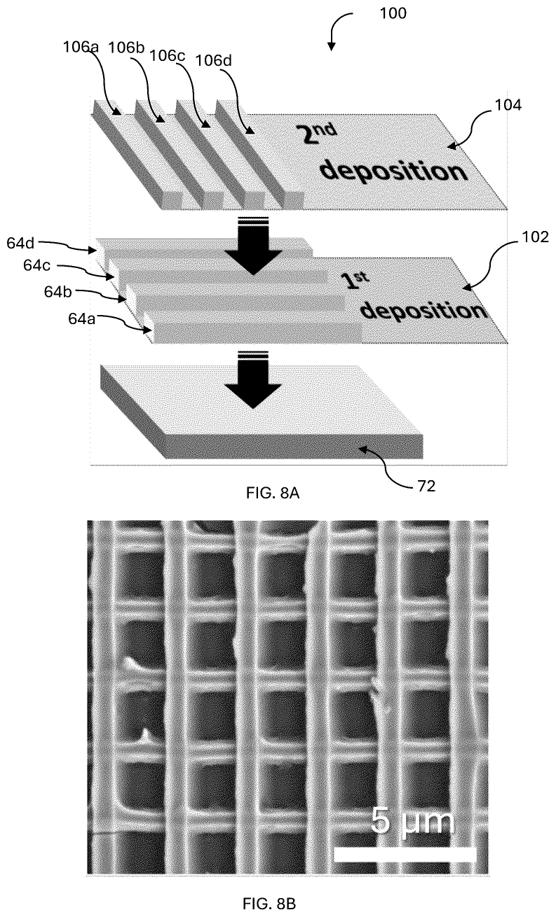

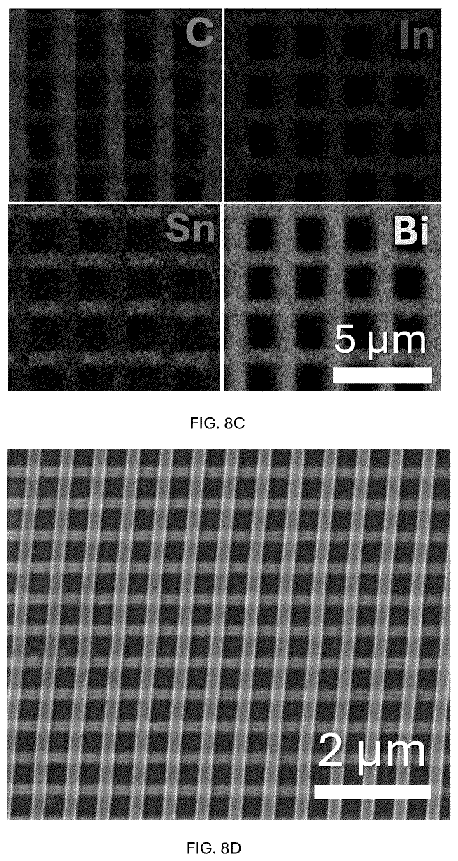

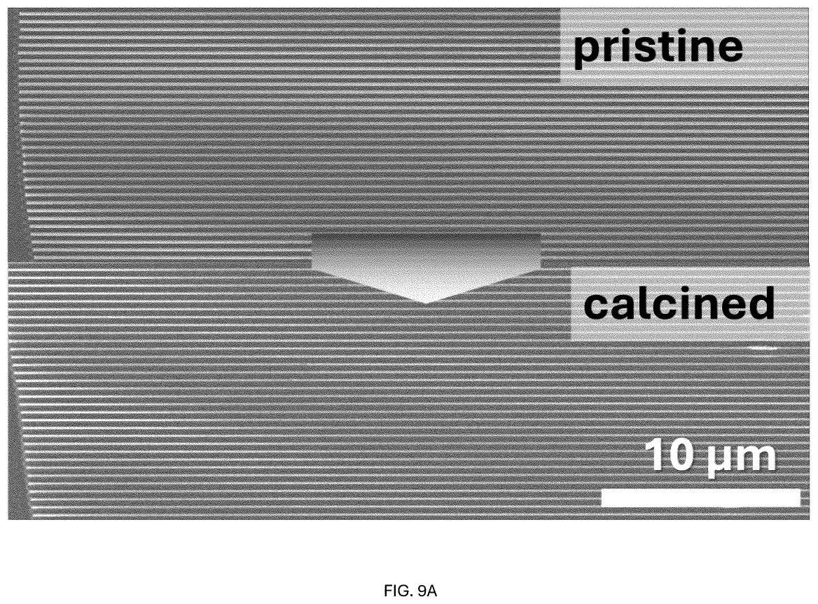

FIG. 8A shows a schematic for the fabrication of a 2-layer array 100. The first deposition layer 102 was made by forming the organometallic deposits 64a-64d on the substrate 72. The mold (not shown) was lifted above the first deposition layer 102 and rotated 90 degrees such that the second deposition layer 104 comprises organometallic deposits 106a-106d that are orthogonal to the first deposition layer 102 organometallic deposits 64a-64d.

Example 5 was repeated to make the first layer array. The first layer was calcined. The substrate with the first layer array was placed in a muffle furnace (KSL1200-X, MTI Corp.) in an ambient atmosphere. The furnace was set at a ramping rate of 10° C./min, kept at 600° C. for an hour. The furnace was turned off and remained closed until the furnace temperature dropped to 100° C. Then the furnace door was opened, and the sample was removed and allowed to cool to ambient conditions.

Then, another 1 μL of undercooled metal particle solution was deposited on the same substrate, and the PDMS template with the closed channels was rotated onto the 1st layer along a 90 degree axis of interest. After repeating the close-channel growth, a 2-layer structured grid array was obtained. FIG. 8B shows a micrograph of the 2-layer array. FIG. 8C is an EDS elemental mapping of the 2-layer array showing homogeneous composition. Another 2-layer structure was made using narrower channels. FIG. 8D shows a micrograph of a 2-layer array with narrower wires than the 2-layer array shown in FIG. 8B.

### Example 9—Heat Treatment of Pristine Arrays Made From Field's Metal Particles

Example 5 was repeated to make an array with microwires (microwire array) and an array with nanowires (nanowire array). For heat-treatment, the obtained pristine micro array and nano array were each placed in a muffle furnace (KSL1200-X, MTI Corp.) in ambient atmosphere. The furnace was set at a ramping rate of 10° C./min, kept at 600° C. for an hour. The furnace was turned off and remained closed until the furnace temperature dropped to 100° C. Then the furnace door was opened and the sample was removed and allowed to cool to ambient conditions.

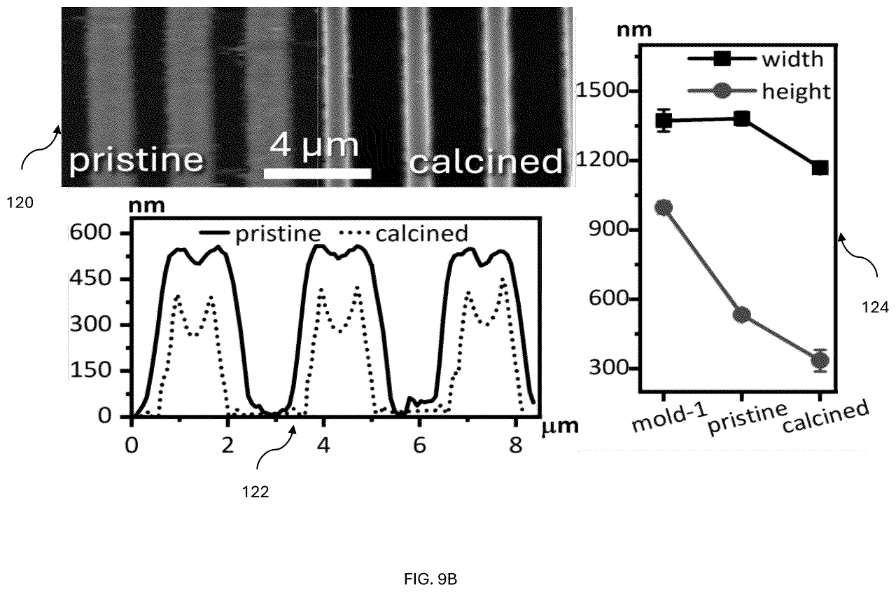

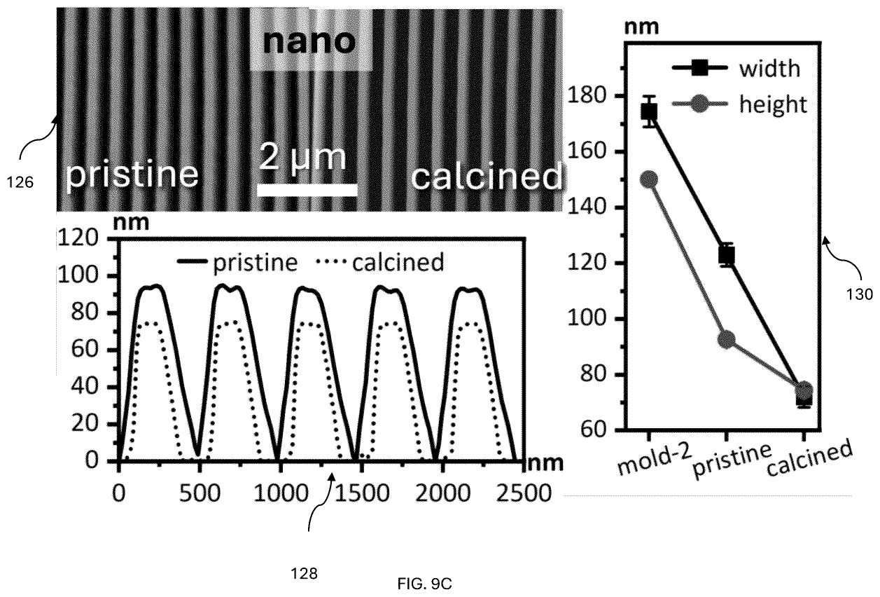

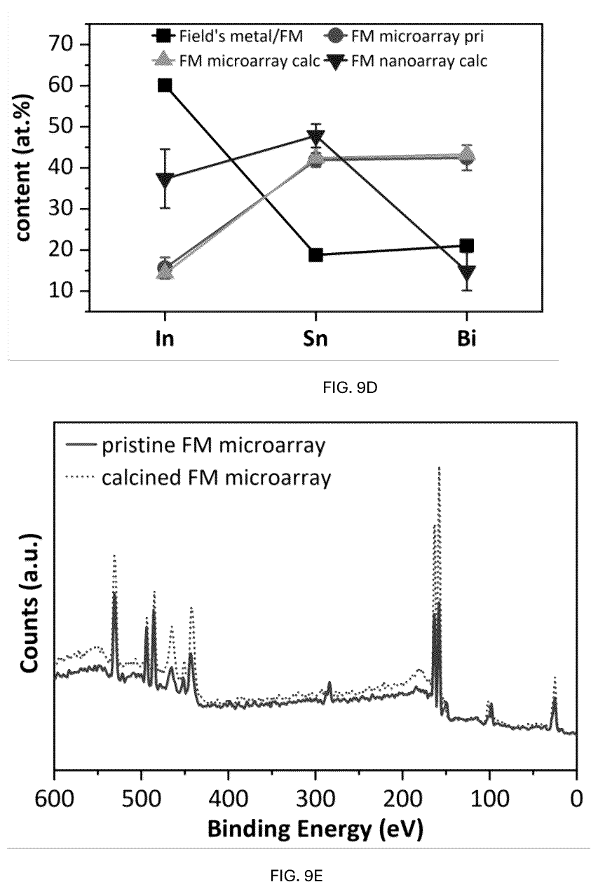

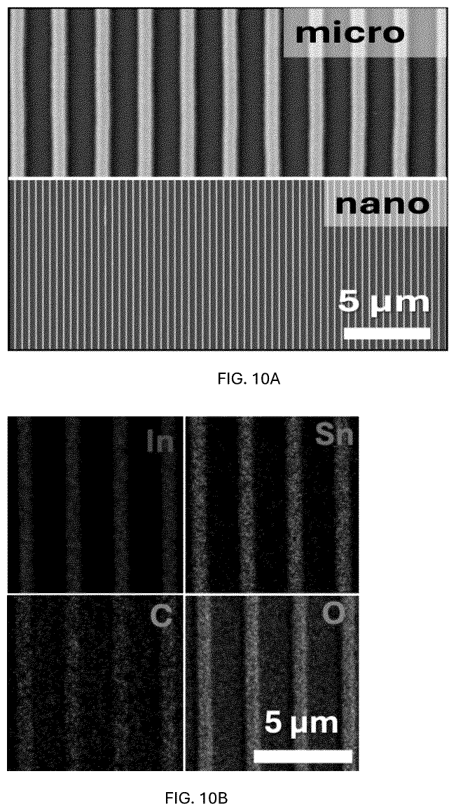

FIG. 9A shows an SEM image of pristine and ambient calcined nanowire array. Heat caused minor defects and breakages in wires. FIG. 9B and FIG. 9C show comparative analysis between the microwire arrays and the nanowire arrays before and after they were calcined. FIG. 9B shows atomic force microscope (AFM) mapping 120, cross-section analysis before and after calcination 122, along with summaries of wire height and width change for the FM microwire arrays 124. FIG. 9C contains atomic force microscope (AFM) mapping 126, cross-section analysis before and after calcination 128, along with summaries of wire height and width change for the FM nanowire arrays 130.

A major advantage of HetMet was the transformation of the organometallic ligand into graphitic carbon leading to tuneable bandgap metal oxides. The wire array morphology, however, might be damaged by heat-treatment. Thus, we studied the array morphology change before and after aerobic calcination. The pristine Field's metal array possesses sharp-edged features with an aspect-ratio up to a thousand (FIG. 9A pristine). After 1-hour calcination at 600° C., the wires remained continuous with minor structural defects (FIG. 9A calcined). Atomic Force microscopy (AFM) revealed a trapezoid shape of pristine microwires with an average 1381.50±29.15 nm in width (w) and 531.63±17.94 nm in height (h), which were reduced to 1168.58±26.88 nm and 334.43±46.88 nm after heat-treatment, respectively (FIG. 9B). Apart from the decrease in cross-section area, the dip at the top centre of the pristine wire was intensified by heat. Despite severe volume shrinkage caused by heat (46.79% assuming constant wire length), continuity preservation of D-Met arrays indicated unique self-assembly microstructures, which phenomenon is prominent for nano-arrays. We observe that the wider the wires, the more deformed they get with a significant increase in buckling. Using a smaller mold leads to lower discrepancies in beam to mold dimensions. When mold channel dimensions are <200 nm (h=174 nm, w=150 nm), wires showed >70% match (h=92 nm, w=122 nm). Upon calcination, these narrower wires lost 24% and 43% in h and w respectively (FIG. 9C).

FIG. 9D is a graph showing the metal elemental contents of Field's metal particle, pristine and calcined Field's metal microwire array as well as calcined Field's metal nanowire array. Elemental mapping in Field's metal pristine arrays revealed a homogeneous distribution across both micro-and nanowires. To further investigate the composition, the ratio of different elements, relative to the alloy, were evaluated. From Field's metal (% atomic 60.1% In, 18.8% Sn and 21.1% Bi translating to % wt 51% In, 16.5% Sn and 32.5% Bi) for clarity, we discuss composition in atomic %. Microwire arrays bearing % at composition; 15.6% In, 41.9% Sn and 42.5% Bi, were realized from Field's metal (FIG. 9D). Post-reaction particle composition was 60% In, 19% Sn and 21% Bi in line with the asymmetric etching of the components. Calcination of microwire arrays did not significantly change the composition (14.3% In, 42.4% Sn, 43.3% Bi). For calcined Field's metal nanoarrays the atomic ratios for In, Sn and Bi were 37.4%, 47.8%, and 14.8%.

The microwire arrays formed using Field's metal (FM) particles, both pristine (Example 5) and calcined, (Example 9) were further characterized using X-ray photoelectron spectrum (XPS) to investigate the electronic states of elements. FIG. 9E is an XPS graph for the pristine and calcined FM microarrays. The survey spectra confirmed the existence of In, Sn, Bi, C and O in both pristine and calcined arrays, with a decrease in C signal intensity confirming the carbon loss. For pristine Field's metal microarrays, the C1s peak at 288.54 eV was attributed to the acetate. To further support the above observations, XPS spectra of calcined FM microarrays were obtained. For all the metallic species, heat-treatment induced shifts in their binding energies towards lower binding energies, with increased intensity of the In3d 442.87 eV peak.

### Example 10: Formation of Pristine and Calcined Arrays Made With Eutectic Indium Tin (IT) Particles

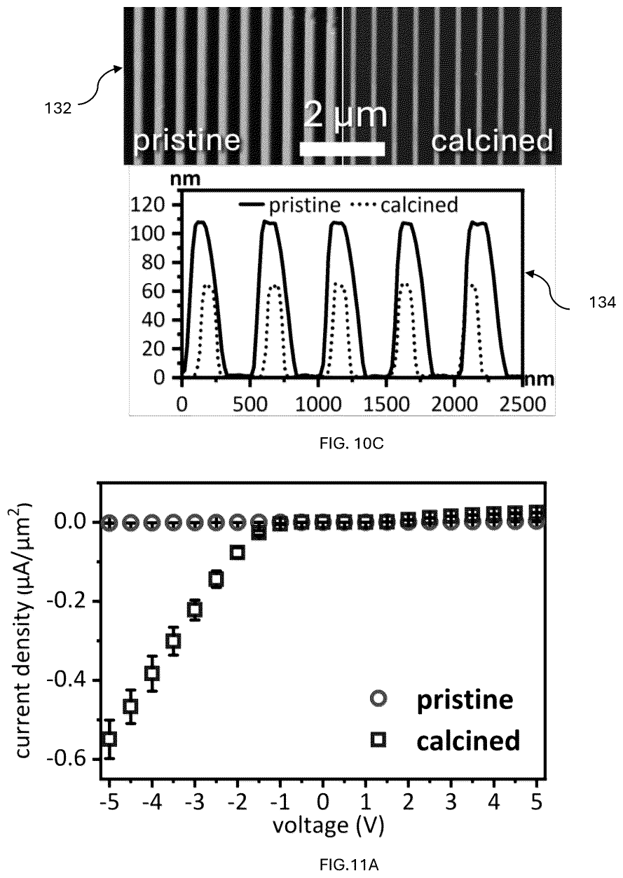

Example 5 was repeated with the eutectic Indium Tin (IT) particles made in Example 1. Different molds were used to make microwires and nanowires. FIG. 10A shows micrographs of the arrays made with microwire-sized wires and with nanowire-sized wires. FIG. 10B shows EDS mapping of D-Met microwire arrays made from eutectic Indium Tin (IT) particles. FIG. 10C shows comparative analysis between the microwire arrays and the nanowire arrays before and after they were calcined. FIG. 10C shows atomic force microscope (AFM) mapping 132 and cross-section analysis before and after calcination 134.

### Example 11—Conductivity Measurement of an Array

The microwire arrays formed using Field's metal (FM) particles, both pristine (Example 5) and calcined, (Example 9) and the microwire arrays formed using the indium/tin eutectic (IT), both pristine (Example 10) and calcined (by the same procedure as Example 9) were tested for electroconductivity.

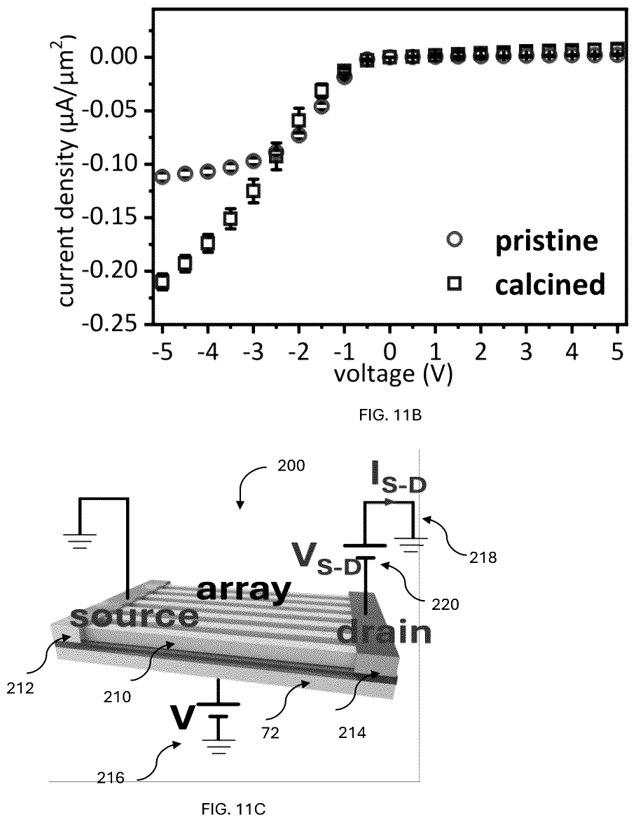

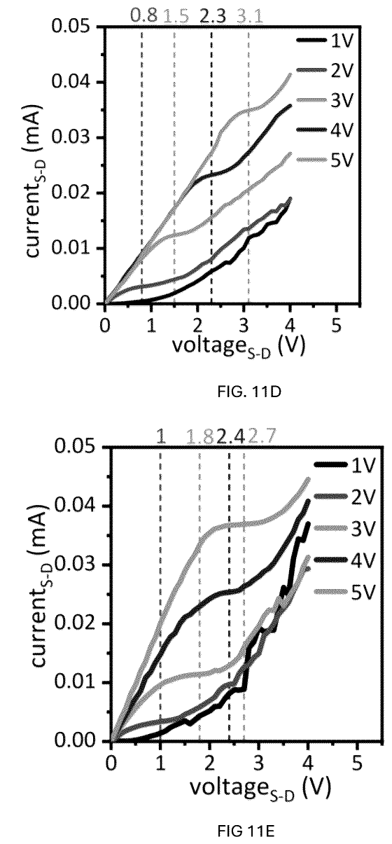

Two Eutectic Gallium Indium (EGaIn) liquid metal droplets (c.a. 0.04 μL) were deposited 1 mm apart onto wires along their length and served as electrodes. A Keithley 6430 Sub-Femtoamp Remote Sourcemeter was connected to the electrodes and applied cyclic voltage (V) from −5 V to 5 V with a 0.5 V step while current (I) was recorded. A hundred I-V cycles were recorded for reaching a steady state. The conductivity setup photo was taken with a ME520TA reflective microscope. FIG. 11A shows the current-voltage plot for pristine and calcined FM microwires and FIG. 11B shows the current-voltage plot for pristine and calcined IT microwires.

Conductivity of the arrays was measured using two Au probes. FIG. 11A shows the current-voltage (I-V) plot for pristine Field's metal microwires with resistivity of 1.7 Ω·m at V>0 (denoted as R+) and 2.49 Ω·m at V<0 (denoted as R−). For calcined wires, R+=1.02 Ω·m which is relatively close to the pristine, while R−=4.56×10⁻² Ω·m, a two-order-of-magnitude decrease. Similarly, pristine arrays from InSn particles had R−=4.48×10⁻² Ω·m, that decreased to R−=2.22×10⁻² Ω·m when calcined (FIG. 11B). The asymmetric conductance indicates diode-like behavior.

To further explore this anisotropic conductance, a three-terminal Field Emission Transistor (FET) was fabricated using the calcined FM microwire array or the calcined IT microwire array. FIG. 11C is a schematic of the Back-gate FET 200, the FET conductivity testing set-up used in Example 11. Back-gate FET 200 was constructed using wire array 210. The Back-gate FET 200 was constructed by connecting gold electrodes to ends of wire array 210 as a source electrode 212 and drain electrode 214. Si substrate 72 was used as back-gate electrode 216, and the intrinsic silica layer on Si substrate served as dielectric in the FET device. 1 to 5 V voltage was applied on Si substrate. Under each applied voltage, the source-drain current IS-D 218 between source electrode 212 and drain electrode 214 was recorded versus the source-gate voltage changed from −4 to +4 V in a step of 0.1V. The measurement was done using an HP 4155B semiconductor analyzer with a probe station.

FIG. 11D is a current-voltage graph of the FM microwire array, and FIG. 11E is a current-voltage graph of the InSn microwire array. Under 1V bias, increasing the source-drain voltage VS-D 220 from 0 to 5 V induced an enhancement of the source-drain current IS-D 218 following a half-exponential function. When V was set to 2V, however, a platform formed in the IS-D-VS-D curve, which is indicative of transistor characteristics. This platform became more defined with an increase in V (FIG. 11D). Calcined wires made from InSn particles showed similar behavior to their Field's metal congeners, albeit with a smaller estimated threshold voltage, i.e., Field's metal wires=1.467 V vs InSn wires=1.267 V (FIG. 11E).

### Example 12—Formation of Individual Units With Electrical Capability

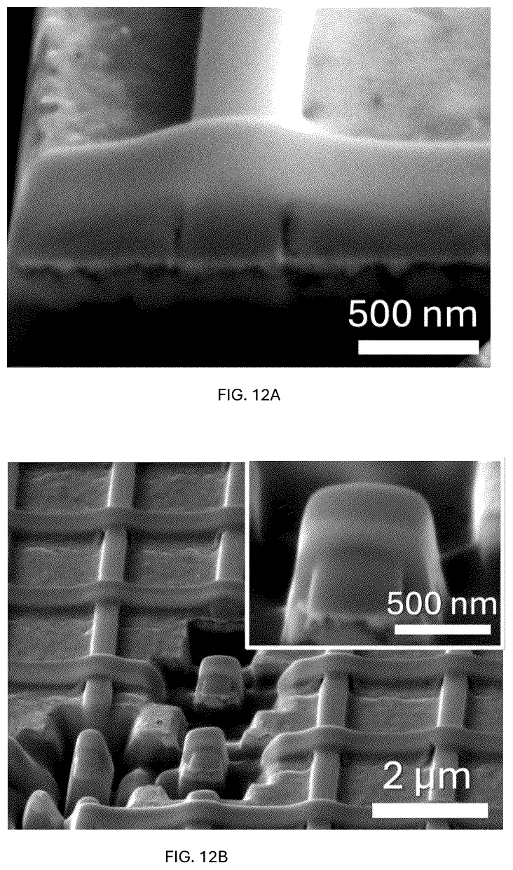

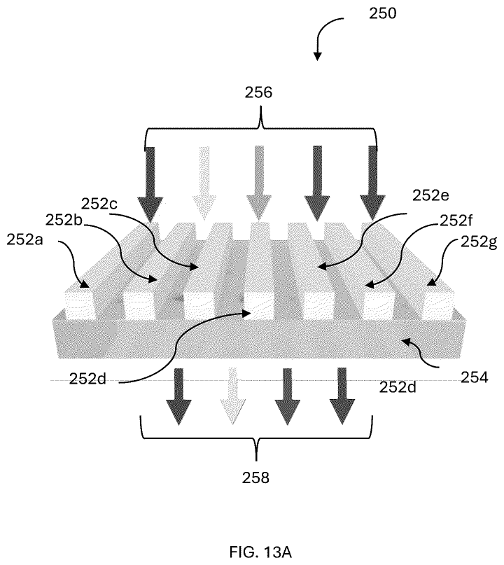

FIG. 12A shows an SEM image of a 2-layer array cross-section highlighting conformal contact points between the 1^{st} and 2^{nd} layers in nanowire arrays. Using fast ion bombardment (FIB) to cut a cross-section of the intersection points on the 2-layer nanowire array revealed conformal contact. These cross-sections can be isolated into free-standing units structurally analogous to some FinFet morphologies. FIG. 12B shows an SEM image of an isolated free-standing unit structurally analogous to some FinFet morphologies. Example 12 demonstrates our ability to make individual electrical functional units form arrays with two or more layers.

### Example 13—Transmission Spectrum Measurement

The microwire arrays formed using Field's metal (FM) particles, both pristine (Example 5) and calcined, (Example 9) and the microwire arrays formed using the indium/tin eutectic (IT), both pristine (Example 10) and calcined (by the same procedure as Example 9) were tested for transmission spectrum.

The transmission spectra of pristine arrays on glass were measured using a home-built device. After mounting the sample on stage, a collimated broadband light (HL-2000, OceanOptics) was applied as a light source and shined vertically on the sample. Transmitted light was collected by fiber and analyzed by an OceanOptics USB2000 spectrometer.

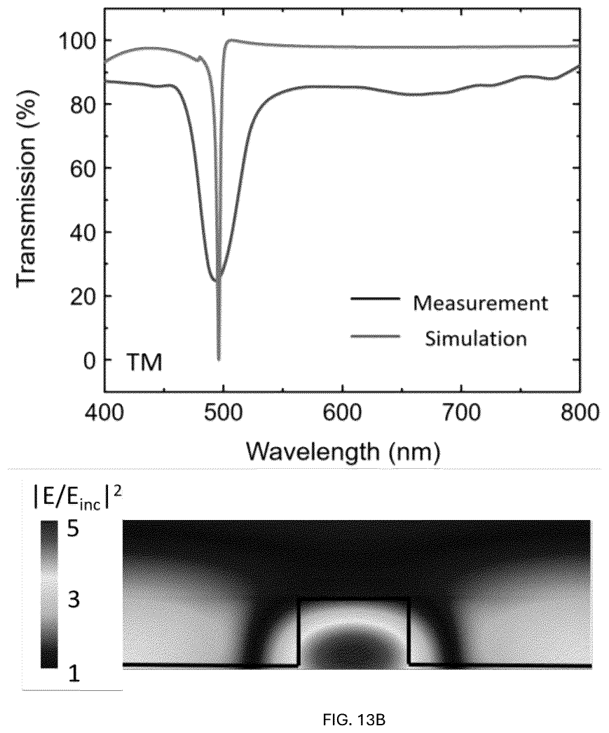

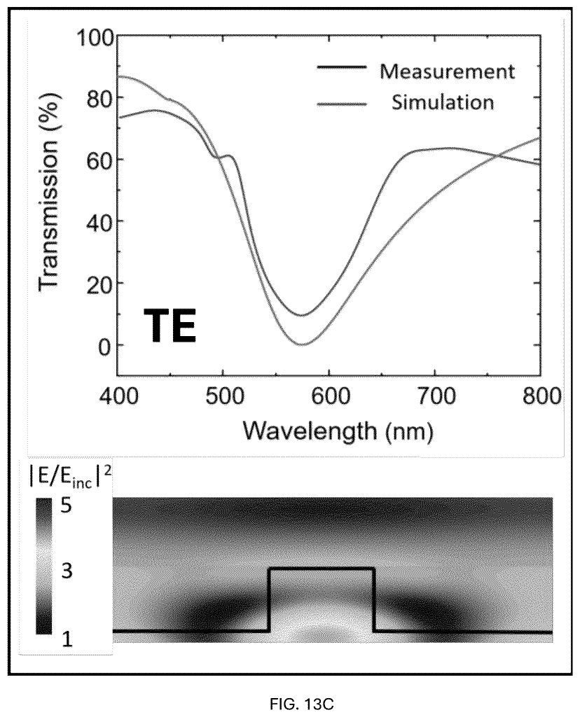

FIG. 13A is a schematic of an optical filter 250. Optical filter 250 has organometallic deposits 252a-252g on a glass substrate 254. Light 256 enters the optical filter 250 from the top and leaves the bottom of optical filter 250 as filtered light 258.

An optical filter (as shown schematically in FIG. 13A) was built by fabricating a pristine nanowire array from InSn particles onto a glass substrate. The refractive index of the above arrays was 1.72-1.82, and an extinction coefficient in the range 0-0.09, in the 400 nm to 500 nm range. The observed refractive index was larger than that of both glass (1.5) and air (1.0), thus satisfying the requirements for guided mode generation. FIG. 13B shows a transmission spectrum under transverse magnetic polarized light and the corresponding simulation result. FIG. 13C shows a transmission spectrum under transverse electric polarized light and the corresponding simulation result. When light incident on the sample was polarized in the transverse magnetic (TM) direction, the transmission spectrum showed a dip at 580 nm (FIG. 13B). A transverse electric (TE) wave caused a similar transmission dip at 500 nm, albeit with a larger dip width compared to the TM wave (FIG. 13C). The measured transmittance spectra aligned with simulation results, indicating great field trapping and enhancement inside the wire arrays.

### Example 14—Formation of Organometallic Deposits With Junctions

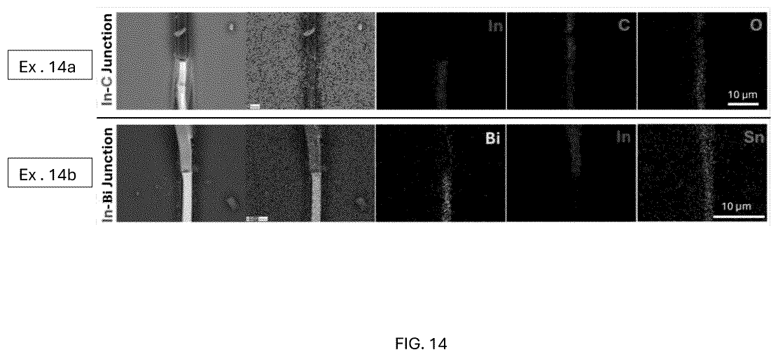

Example 5 was repeated with single-component metal particles. Example 14a used only In particles and Example 14b used In, Bi, and Sn particles. FIG. 14 shows SEM and EDS images of the In—C junction on the left/top and the In—Bi junction on the right/bottom. The junction formation was observed when the applied mold had a channel dimension: 5 μm width, 1 μm height, and 5 mm length. The EDS images of the Example 14A deposits made with only In particles show that the In is only in about the first half of the deposit. The EDS images for Example 14B show that Bi is mostly in the first half of the deposit and that In is mostly in the second half of the deposit. Without being bound to any theory, the wider channel may allow for faster evaporation of the solvent, leading to the junction formation.

### Example 15—Formation of Organometallic Deposits From Single-component Metal Particles

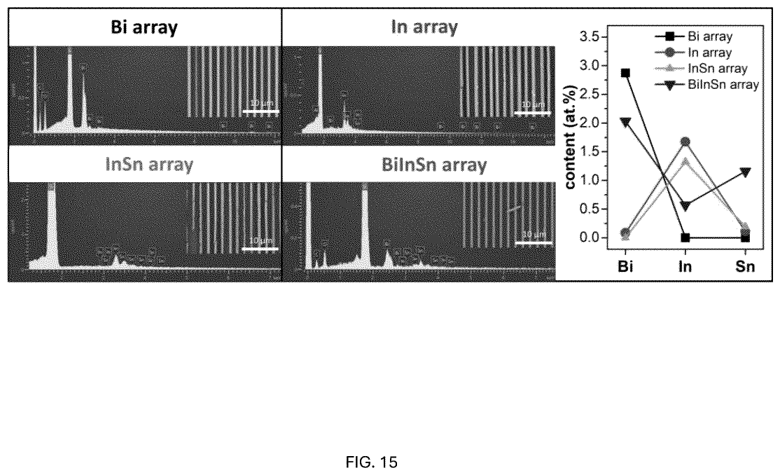

Example 5 was repeated with single-component metal particles. The Bi array was made with Bi particles. The In array was made with In particles. The InSn array was made with a mixture of In particles and Sn particles. The BiInSn array was made with a mixture of Bi particles, In particles, and Sn particles. FIG. 15 shows SEM and EDS spectrographs corresponding to the arrays made in Example 15. The graph is a summary of the amount of metals in each array.

### Example 16—Formation of Arrays Onto Curved Substrates

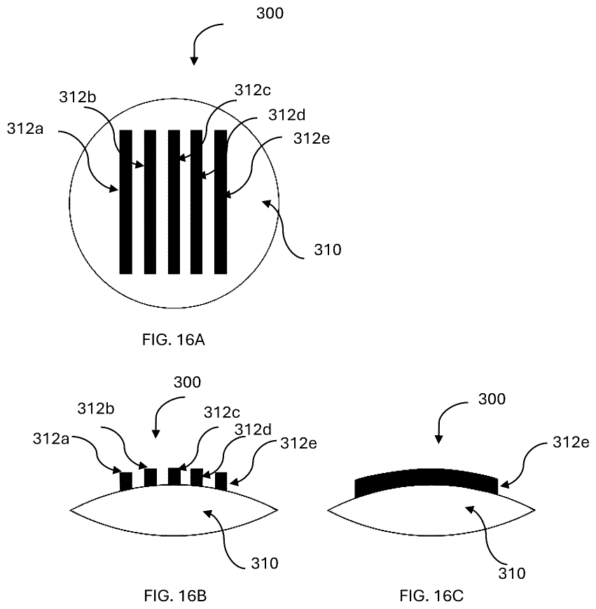

FIG. 16A is a top view schematic of an array made with a curved substrate 300 in Example 16. FIG. 16B is a front view schematic of the array made with the curved substrate 300 used in Example 16. FIG. 16C is a side view schematic of the array made with the curved substrate 300 used in Example 16. Arrays were formed using Field metal particles in accordance with Example 5, but with a curved substrate 310 and corresponding mold (not shown) that facilitated the production of organometallic deposits 312a-312e with an overall curved shape.

Although the present invention has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present invention and are intended to be covered by the following claims.

What is claimed is:

1. A method for forming an array, the method comprising:
a) forming a layerₓ on a substrate,
wherein x=1, the layerₓ is a layer₁, and the layer₁ is attached to the substrate,
wherein the forming of the layerₓ comprises forming organometallic deposits,
wherein the forming of the organometallic deposits comprises:
i) providing a solution to openings of channels;
ii) forming and pinning down organometallic adducts as the solution penetrates the channels; and
iii) evaporating at least a portion of the solution to form the organometallic deposits,
wherein the solution comprises synthon metal ions, an acid, and a solvent;
wherein the solution is formed by etching metal particles with the acid and the solvent proximate the openings or feeding the solution through the openings,
wherein each of the organometallic deposits comprises a wire, a shape, and/or a functional unit, and
wherein each of the organometallic deposits has a micro and/or a nano dimension.

2. The method of claim 1, further comprising:
b) forming a layer₍ₓ₊₁₎ adjacent to the layerₓ along an axis of interest; and
c) incrementing x by 1 and repeating step b) until a set number of layers is reached,
wherein the forming of each of the layer₍ₓ₊₁₎ comprises the forming of the organometallic deposits,
wherein the axis of interest of the layer₍ₓ₊₁₎ and the axis of interest of the layerₓ are different, and
wherein the set number of layers is at least 2.

3. The method of claim 1, wherein the metal particles comprise a transition metal, a p-block metal, a rare earth metal, a group I metal, and/or a group II metal.

4. The method of claim 1, wherein the solvent comprises water, an alcohol, a ketone,
an amine, an amide and/or a thiol, and/or
wherein the acid is represented by formula R X₁X₂X₃H, and
wherein R is a C₁-C₂₀ hydrocarbyl group; X₁ is C, N, or P; and X₂ and X₃ are independently O, P, N, or S.

5. The method of claim 1, wherein the substrate comprises a ceramic, a polymer, a metal, or glass, and/or wherein the substrate has a curved shape.

6. The method of claim 1, wherein layer₁ comprises at least 50 organometallic deposits, and wherein an area of the array is at least 1 mm².

7. The method of claim 1, wherein the array is capable of functioning as a metamaterial, a waveguide, a photonic diode, and/or a guided-mode resonance device.

8. The method of claim 2, further comprising:
d) calcining the layer₁ and/or at least one of the layer₍ₓ₊₁₎; and/or
e) plasma processing the layer₁ and/or at least one of the layer₍ₓ₊₁₎.

9. The method of claim 2, wherein a difference between the axis of interest for each of the layerₓ and for each of the layer₍ₓ₊₁₎ varies between 5 degrees and 175 degrees.

10. The method of claim 2, wherein on the layer₁ and each of the layer₍ₓ₊₁₎ at least a portion of the organometallic deposits have a height ranging from 1 nm to 10 μm, a width ranging from 20 nm to 100 μm, and a length ranging from 100 nm to 450 mm.

11. The method of claim 2, wherein on the layer₁ or any of the layer₍ₓ₊₁₎ at least a portion of the organometallic deposits comprise a shape, and
wherein the shape is selected from the group consisting of 2D manifestations of an angle, 3D manifestations of an angle, a curvature, a right angle corner, a zig-zag, a pattern of (i) departing from a fixed point, (ii) proceeding down a first length, (iii) returning to the fixed point, and proceeding down a second length, or a pattern comprising periodic functional units.

12. The method of claim 11, wherein the shape of at least a portion of the organometallic deposits on a first layer selected from the layer₁ or the layer₍ₓ₊₁₎ and the shape of at least a portion of the organometallic deposits on a second layer selected from the layer₁ or the layer₍ₓ₊₁₎ is different.

13. The method of claim 2, wherein on the layer₁ and each of the layer₍ₓ₊₁₎ a periodicity of at least a portion of the organometallic deposits ranges from 1 nm to 50 mm.

14. The method of claim 2, wherein the layer₁ and any of the layer₍ₓ₊₁₎ has a 3D feature, wherein at least one of the organometallic deposits has a height greater than 10 μm to 100 μm along at least a portion of a length, and/or wherein at least two consecutive layers of the layer₁ or the one or more layer₍ₓ₊₁₎ in combination has a 3D feature.

15. The method of claim 2, wherein a composition of at least one of the layer₁ or any of the layer₍ₓ₊₁₎ varies across the array.

16. The method of claim 2, wherein the array comprises a light Guiding Component, a Phase & Wavefront Control Component, a Direction & Routing Component, a Filtering & Spectral Control Component, a Light Generation Component, a Detection Component, a Modulation Component, and/or a Resonant/Energy Storage Component.

17. A method for forming an array, the method comprising:
a) forming a layerₓ,
b) forming a layer₍ₓ₊₁₎ adjacent to the layerₓ along an axis of interest; and
c) incrementing x by 1 and repeating step b) until a set number of layers is reached,
wherein when x=1, the layerₓ is layer₁, and layer₁ is attached to a substrate,
wherein the forming of the layerₓ and of the layer₍ₓ₊₁₎ comprises forming organometallic deposits,
wherein the axis of interest of the layer₍ₓ₊₁₎ and the axis of interest of the layerₓ are different,
wherein the forming of the organometallic deposits comprises:
i) providing a solution to openings of channels;
ii) forming and pinning down organometallic adducts as the solution penetrates the channels; and
iii) evaporating at least a portion of the solution to form the organometallic deposits,
wherein the solution comprises synthon metal ions, an acid, and a solvent;
wherein the solution is formed by etching metal particles with the acid and the solvent proximate the openings or feeding the solution through the openings,
wherein each of the organometallic deposits comprises a wire, a shape, and/or a functional unit, and
wherein each of the organometallic deposits has a micro and/or a nano dimension.

18. The method of claim 17, wherein the metal particles comprise a transition metal, a p-block metal, a rare earth metal, a group I metal, and/or a group II metal, wherein the solvent comprises water, an alcohol, a ketone, an amine, an amide, and/or a thiol,
wherein the acid is represented by formula R X₁X₂X₃H, and
wherein R is a C₁-C₂₀ hydrocarbyl group; X₁ is C, N or P ; X₂ and X₃ are independently O, P, N, or S.

19. The method of claim 17, wherein the array is capable of functioning as a metamaterial, a waveguide, a photonic diode, and/or a guided-mode resonance device.

20. An array comprising at least one layer,
wherein the at least one layer comprises organometallic deposits,
wherein the organometallic deposits have a micro and/or a nano dimension, and
wherein the organometallic deposits comprise a wire, a shape, and/or a functional unit.
